(19) United States
(12) Patent Application Publication
(10) Pub. No.: US 2025/0040352 A1
(43) Pub. Date: Jan. 30, 2025

(54) DISPLAY PANEL AND MANUFACTURING METHOD FOR THE SAME

(71) Applicant: Samsung Display Co., Ltd., Yongin-si (KR)

(72) Inventors: YOUNG SUK LEE, Yongin-si (KR); YONG JUN PARK, Yongin-si (KR)

(21) Appl. No.: 18/637,289

(22) Filed: Apr. 16, 2024

(30) Foreign Application Priority Data
Jul. 28, 2023 (KR) 10-2023-0099219

(51) Int. Cl. H10K 59/122; H10K 59/12; H10K 59/35; H10K 59/80; H10K 59/88

(52) U.S. Cl. CPC H10K 59/122; H10K 59/1201; H10K 59/352; H10K 59/873; H10K 59/88

(57) ABSTRACT

Disclosed is a display panel including a barrier wall defining a barrier wall opening and an inspection opening, and including a first barrier wall layer, and a second barrier wall layer above the first barrier wall layer, and an inspection pattern in the inspection opening, and including a same material as the first barrier wall layer, wherein the barrier wall opening includes a first region defined by an inner surface of the first barrier wall layer, and a second region defined by an inner surface of the second barrier wall layer, and having a smaller width than a width of the first region.

### CROSS-REFERENCE TO RELATED APPLICATIONS

The present application claims priority to, and the benefit of, Korean Patent Application No. 10-2023-0099219, filed on Jul. 28, 2023, in the Korean Intellectual Property Office, the entire disclosure of which is incorporated herein by reference.

### BACKGROUND

### 1. Field

Embodiments of the present disclosure described herein relate to a display panel with improved process reliability and a manufacturing method thereof.

### 2. Description of the Related Art

A display device, such as a television, a monitor, a smart phone, a tablet computer, or the like, which provides an image to a user includes a display panel that displays an image. Various display panels, such as a liquid crystal display panel, an organic light-emitting display panel, an electro wetting display panel, an electrophoretic display panel, and the like, are being developed.

The organic light-emitting display panel may include anodes, a cathode, and emission patterns. The emission patterns may be separated for respective emissive regions, and the cathode may provide a common voltage for the respective emissive regions.

### SUMMARY

Embodiments of the present disclosure provide a display panel with improved process reliability that includes light-emitting elements formed without the use of a metal mask, and a method for manufacturing the display panel.

According to one or more embodiments, a display panel includes a barrier wall defining a barrier wall opening and an inspection opening, and including a first barrier wall layer, and a second barrier wall layer above the first barrier wall layer, and an inspection pattern in the inspection opening, and including a same material as the first barrier wall layer, wherein the barrier wall opening includes a first region defined by an inner surface of the first barrier wall layer, and a second region defined by an inner surface of the second barrier wall layer, and having a smaller width than a width of the first region.

The inspection opening may include a third region defined by an inner surface of the first barrier wall layer, and a fourth region defined by an inner surface of the second barrier wall layer, wherein the inspection pattern is in the third region, and is not in the fourth region.

The inspection opening may be provided in plural, wherein the inspection pattern is provided in plural, the inspection patterns being respectively in the inspection openings.

The inspection patterns may be provided in plural, wherein the inspection pattern is provided in plural, wherein the inspection patterns having different respective widths are in each of the inspection openings.

The display panel may further include a light-emitting element in the barrier wall opening, and including an anode, an emission pattern, and a cathode contacting the barrier wall in the barrier wall opening.

The display panel may further include a thin film encapsulation layer above the light-emitting element, and contacting the inspection pattern.

According to one or more embodiments, a method for manufacturing a display panel includes forming a preliminary barrier wall including a first preliminary barrier wall layer, and a second preliminary barrier wall layer above the first preliminary barrier wall layer, firstly etching the preliminary barrier wall to form initial inspection patterns, and secondly etching the preliminary barrier wall to form a barrier wall including a first barrier wall layer, and a second barrier wall layer above the first barrier wall layer, and to form an inspection pattern from the initial inspection patterns, the inspection pattern including a same material as the first barrier wall layer.

The firstly etching may include etching the first preliminary barrier wall layer and the second preliminary barrier wall layer, wherein the secondly etching includes etching the first preliminary barrier wall layer.

The initial inspection patterns may include a first initial inspection pattern layer patterned from the first preliminary barrier wall layer, and a second initial inspection pattern layer patterned from the second preliminary barrier wall layer.

The initial inspection patterns may include a first initial inspection pattern, and a second initial inspection pattern having a greater width than the first initial inspection pattern, wherein the secondly etching includes removing the first initial inspection pattern, removing the second initial inspection pattern layer of the second initial inspection pattern, and allowing a portion of the first initial inspection pattern layer of the second initial inspection pattern to remain to form the inspection pattern.

The secondly etching may include forming a tip portion including a portion of the second barrier wall layer protruding further than the first barrier wall layer.

The method may further include determining a length of the tip portion based on whether the initial inspection patterns are removed by the secondly etching.

The method may further include forming a preliminary measurement pattern including a first preliminary measurement layer including a same material as the first preliminary barrier wall layer, and a second preliminary measurement layer including a same material as the second preliminary barrier wall layer above the first preliminary measurement layer, etching the preliminary measurement pattern to form initial measurement patterns, etching the initial measurement patterns having different respective widths to form a measurement pattern, and predicting a length of the tip portion.

The etching of the preliminary measurement pattern may be performed under substantially a same etching condition as the firstly etching of the preliminary barrier wall, wherein the etching of the initial measurement patterns is performed under substantially a same etching condition as the secondly etching of the preliminary barrier wall.

The initial measurement patterns may include a first initial measurement layer patterned from the first preliminary measurement layer, and a second initial measurement layer patterned from the second preliminary measurement layer.

The initial measurement patterns may include a first type pattern and a second type pattern, wherein the etching of the initial measurement patterns includes removing the first type pattern, removing the second initial measurement layer of the second type pattern, and allowing a portion of the first initial measurement layer of the second type pattern to remain to form the measurement pattern.

The predicting the length of the tip portion may include predicting a lower limit of the length to be substantially equal to a width of the removed first type pattern.

The predicting the length of the tip portion may include predicting the length to be a difference between a width of the second type pattern and a width of the measurement pattern.

According to one or more embodiments, a method for manufacturing a display panel includes forming initial measurement patterns including a first initial measurement layer, and a second initial measurement layer above the first initial measurement layer, forming a measurement pattern from the initial measurement patterns by allowing the first initial measurement layer of one initial measurement pattern among the initial measurement patterns to remain, and by removing the second initial measurement layer of the one initial measurement pattern, predicting a length of a tip portion through the measurement pattern, and forming a barrier wall having the tip portion defined therein, and including a first barrier wall layer including a same material as the first initial measurement layer, and a second barrier wall layer above the first barrier wall layer and including a same material as the second initial measurement layer.

The forming of the barrier wall may include forming a preliminary barrier wall including a first preliminary barrier wall layer, and a second preliminary barrier wall layer above the first preliminary barrier wall layer, firstly etching the preliminary barrier wall such that the first preliminary barrier wall layer and the second preliminary barrier wall layer are etched, and secondly etching the preliminary barrier wall such that the first preliminary barrier wall layer is etched, wherein the forming of the initial measurement patterns is performed under substantially a same etching condition as the firstly etching, and wherein the forming of the measurement pattern is performed under substantially a same etching condition as the secondly etching.

### BRIEF DESCRIPTION OF THE FIGURES

The above and other aspects of the present disclosure will become apparent by describing in detail embodiments thereof with reference to the accompanying drawings.

FIG. 1A is a perspective view of a display device according to one or more embodiments of the present disclosure.

FIG. 1B is an exploded perspective view of the display device according to one or more embodiments of the present disclosure.

FIG. 2 is a sectional view of a display panel according to one or more embodiments of the present disclosure.

FIG. 3 is a plan view of the display panel according to one or more embodiments of the present disclosure.

FIG. 4 is an enlarged plan view of a portion of a display region of the display panel according to one or more embodiments of the present disclosure.

FIG. 5 is an enlarged sectional view of a partial region of the display panel according to one or more embodiments of the present disclosure.

FIG. 6 is a sectional view of the display panel taken along the line I-I′ of FIG. 4 according to one or more embodiments of the present disclosure.

FIG. 7 is an enlarged plan view illustrating some components of the display panel according to one or more embodiments of the present disclosure.

FIG. 8 is a sectional view of the display panel taken along the line II-II′ of FIG. 7 according to one or more embodiments of the present disclosure.

FIG. 9 is a sectional view of the display panel taken along the line II-II′ of FIG. 7 according to one or more embodiments of the present disclosure.

FIG. 10 is a flowchart illustrating a display panel manufacturing method according to one or more embodiments of the present disclosure.

FIGS. 11A to 11E are sectional views illustrating some of the operations of the display panel manufacturing method according to one or more embodiments of the present disclosure.

FIGS. 12A to 12C are sectional views illustrating some of the operations of the display panel manufacturing method according to one or more embodiments of the present disclosure.

FIG. 13 is a flowchart illustrating a display panel manufacturing method according to one or more embodiments of the present disclosure.

FIG. 14 is a sectional view illustrating a part of operations of the display panel manufacturing method according to one or more embodiments of the present disclosure.

FIG. 15A is a sectional view illustrating a part of the operations of the display panel manufacturing method according to one or more embodiments of the present disclosure.

FIG. 15B is a plan view illustrating a part of the operations of the display panel manufacturing method according to one or more embodiments of the present disclosure.

FIG. 16A is a sectional view illustrating a part of the operations of the display panel manufacturing method according to one or more embodiments of the present disclosure.

FIG. 16B is a plan view illustrating a part of the operations of the display panel manufacturing method according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

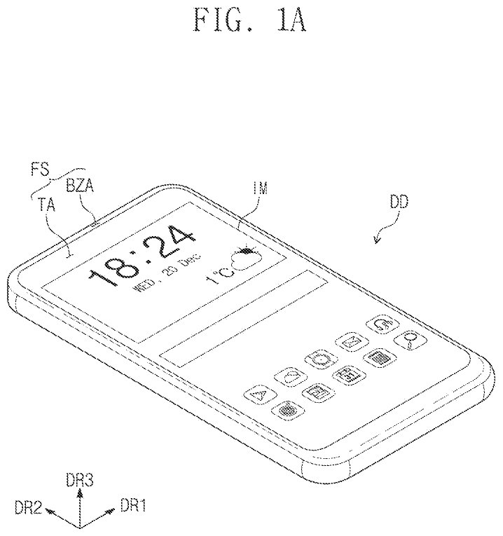

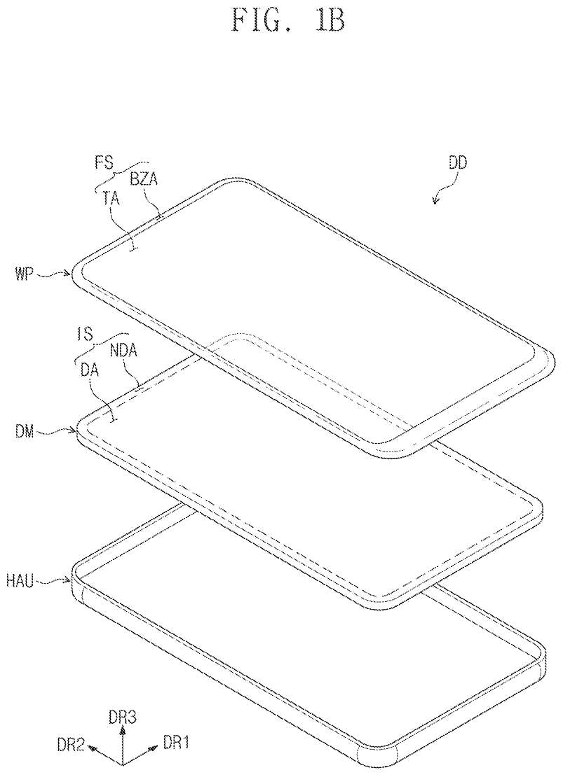

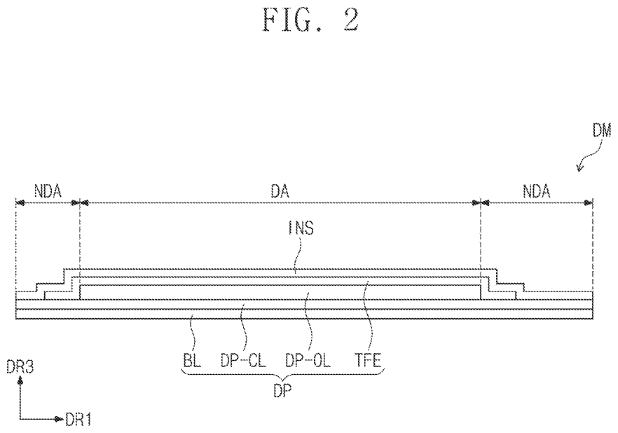

FIG. 1A is a perspective view of a display device according to one or more embodiments of the present disclosure. FIG. 1B is an exploded perspective view of the display device according to one or more embodiments of the present disclosure. FIG. 2 is a sectional view of a display panel according to one or more embodiments of the present disclosure.

In one or more embodiments, the display device DD may be a large electronic device, such as a television, a monitor, or a billboard. Alternatively, the display device DD may be a small and medium-sized electronic device, such as a personal computer, a notebook computer, a personal digital terminal, a car navigation unit, a game machine, a smart phone, a tablet computer, or a camera. However, these devices are merely illustrative, and the display device DD may be employed as other display devices without departing from the spirit and scope of the present disclosure. The display device DD is illustrated as a smart phone.

Referring to FIGS. 1A, 1B, and 2, the display device DD may display an image IM in a third direction DR3 on a display surface FS that is parallel to a first direction DR1 and a second direction DR2. The image IM may include a still image as well as a dynamic image. In FIG. 1A, a clock window and icons are illustrated as examples of the image IM. The display surface FS on which the image IM is displayed may correspond to the front surface of the display device DD.

Front surfaces (or, upper surfaces) and rear surfaces (or, lower surfaces) of members are defined based on the direction in which the image IM is displayed. The front surfaces and the rear surfaces may face away from each other in the third direction DR3, and the normal directions of the front surfaces and the rear surfaces may be parallel to the third direction DR3. Meanwhile, the directions indicated by the first to third directions DR1, DR2, and DR3 may be relative concepts and may be changed to other directions. As used herein, the expression “from above a plane” may mean that it is viewed in the third direction DR3.

As illustrated in FIG. 1B, the display device DD may include a window WP, a display module DM, and a housing HAU. The window WP and the housing HAU may be coupled with each other to form the exterior of the display device DD.

The window WP may include an optically clear insulating material. For example, the window WP may include glass or plastic. The front surface of the window WP may define the display surface FS of the display device DD. The display surface FS may include a transmission region TA and a bezel region BZA. The transmission region TA may be an optically clear region. For example, the transmission region TA may be a region having a visible light transmittance of about 90% or more.

The bezel region BZA may be a region having a lower light transmittance than the transmission region TA. The bezel region BZA may define the shape of the transmission region TA. The bezel region BZA may be adjacent to the transmission region TA and may surround the transmission region TA (e.g., in plan view). Meanwhile, this is illustrative, and in the window WP according to one or more embodiments of the present disclosure, the bezel region BZA may be omitted. The window WP may include at least one of an anti-fingerprint layer, a hard coating layer, or an anti-reflection layer, and is not particularly limited.

The display module DM may be located under the window WP. The display module DM may be a component that substantially generates the image IM. The image IM generated by the display module DM is displayed on a display surface IS of the display module DM and visually recognized by a user from the outside through the transmission region TA.

The display module DM includes a display region DA and a non-display region NDA. The display region DA may be a region activated depending on an electrical signal. The non-display region NDA is adjacent to the display region DA. The non-display region NDA may surround the display region DA. The non-display region NDA may be a region covered by the bezel region BZA and may not be visible from the outside.

As illustrated in FIG. 2, the display module DM may include the display panel DP and an input sensor INS. In one or more embodiments, the display device DD (refer to FIG. 1A) may further include a protective member located on the lower surface of the display panel DP, and an anti-reflection member and/or a window member located on the upper surface of the input sensor INS.

The display panel DP may be an emissive display panel. However, this is illustrative, and the present disclosure is not particularly limited thereto. For example, the display panel DP may be an organic light-emitting display panel or an inorganic light-emitting display panel. An emissive layer in the organic light-emitting display panel may include an organic luminescent material. An emissive layer in the inorganic light-emitting display panel may include quantum dots, quantum rods, or micro LEDs. Hereinafter, it will be exemplified that the display panel DP is an organic light-emitting display panel.

The display panel DP may include a base layer BL, and a circuit element layer DP-CL, a display element layer DP-OL, and a thin film encapsulation layer TFE that are located on the base layer BL. The input sensor INS may be directly located on the thin film encapsulation layer TFE. As used herein, the expression “component A is directly located on component B” means that an adhesive layer is not located between component A and component B.

The base layer BL may include at least one plastic film. The base layer BL may be a flexible substrate, and may include a plastic substrate, a glass substrate, a metal substrate, or an organic/inorganic composite substrate. The display region DA and the non-display region NDA described above with reference to FIG. 1B may be identically defined in the base layer BL.

The circuit element layer DP-CL may include at least one insulating layer and a circuit element. The insulating layer includes at least one inorganic layer and at least one organic layer. The circuit element includes signal lines and a pixel drive circuit.

The display element layer DP-OL may include a barrier wall and light-emitting elements. Each of the light-emitting elements may include an anode, an intermediate layer, and a cathode.

The thin film encapsulation layer TFE may include a plurality of thin films. Some of the thin films may be located to improve optical efficiency, and the other thin films may be located to protect organic light-emitting diodes.

The input sensor INS obtains coordinate information of an external input. The input sensor INS may have a multi-layer structure. The input sensor INS may include a single conductive layer or multiple conductive layers. Furthermore, the input sensor INS may include a single insulating layer or multiple insulating layers. The input sensor INS may sense the external input in a capacitive type. However, this is illustrative, and the present disclosure is not limited thereto. For example, in one or more embodiments, the input sensor INS may sense the external input using an electromagnetic induction method or a pressure sensing method. Meanwhile, in one or more embodiments of the present disclosure, the input sensor INS may be omitted.

As illustrated in FIG. 1B, the housing HAU may be coupled with the window WP. The housing HAU may be coupled with the window WP to provide an inner space. The display module DM may be accommodated in the inner space.

The housing HAU may include a material having a relatively high rigidity. For example, the housing HAU may include glass, plastic, or metal, or may include a plurality of frames and/or plates formed of a combination of the aforementioned materials. The housing HAU may stably protect components of the display device DD accommodated in the inner space from an external impact.

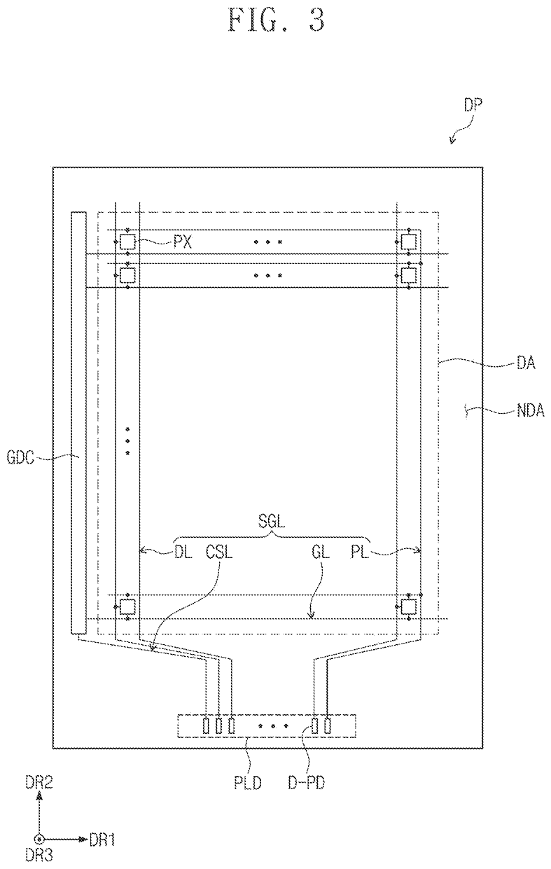

FIG. 3 is a plan view of the display panel according to one or more embodiments of the present disclosure.

Referring to FIG. 3, a display region DA, and a non-display region NDA around the display region DA, may be defined in the display panel DP. The display panel DP may include pixels PX, and signal lines SGL electrically connected to the pixels PX. The display panel DP may include a drive circuit GDC and a pad part PLD. The display region DA and the non-display region NDA may be distinguished from each other based on locations of the pixels PX. The pixels PX may be located in the display region DA. The drive circuit GDC and the pad part PLD may be located in the non-display region NDA.

The pixels PX may be arranged in the first direction DR1 and the second direction DR2. The pixels PX may include a plurality of pixel rows that extend in the first direction DR1 and that are arranged in the second direction DR2, and a plurality of pixel columns that extend in the second direction DR2 and that are arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the drive circuit GDC and may provide control signals to the drive circuit GDC.

The drive circuit GDC may include a gate drive circuit. The gate drive circuit may generate gate signals and may sequentially output the generated gate signals to the gate lines GL. The gate drive circuit may additionally output other control signals to the pixel drive circuit.

The pad part PLD may be a part to which a flexible circuit board is connected. The pad part PLD may include pixel pads D-PD, and the pixel pads D-PD may be pads for connecting the flexible circuit board to the display panel DP. Each of the pixel pads D-PD may be connected with a corresponding signal line among the signal lines SGL. The pixel pads D-PD may be connected to the corresponding pixels PX through the signal lines SGL. Furthermore, one pixel pad among the pixel pads D-PD may be connected to the drive circuit GDC.

In addition, the pad part PLD may further include input pads. The input pads may be pads for connecting a flexible circuit board to the input sensor INS (refer to FIG. 2). However, without being limited thereto, the input pads may be located on the input sensor INS (refer to FIG. 2), and may be connected with the pixel pads D-PD through a separate circuit board. Alternatively, the input sensor INS (refer to FIG. 2) may be omitted, and the input pads may not be additionally included.

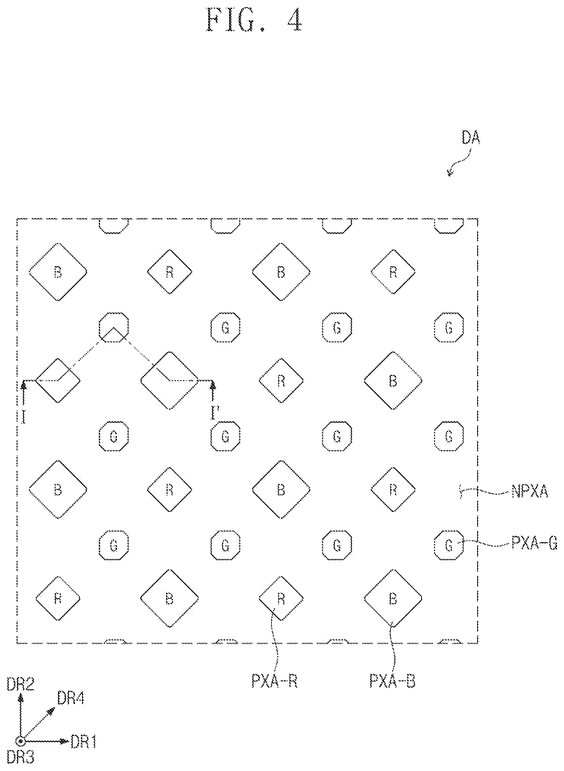

FIG. 4 is an enlarged plan view of a portion of the display region of the display panel according to one or more embodiments of the present disclosure. FIG. 4 is a plan view of the display module DM as viewed from above the display surface IS (refer to FIG. 1B) of the display module DM (refer to FIG. 1B), and illustrates an arrangement of emissive regions PXA-R, PXA-G, and PXA-B.

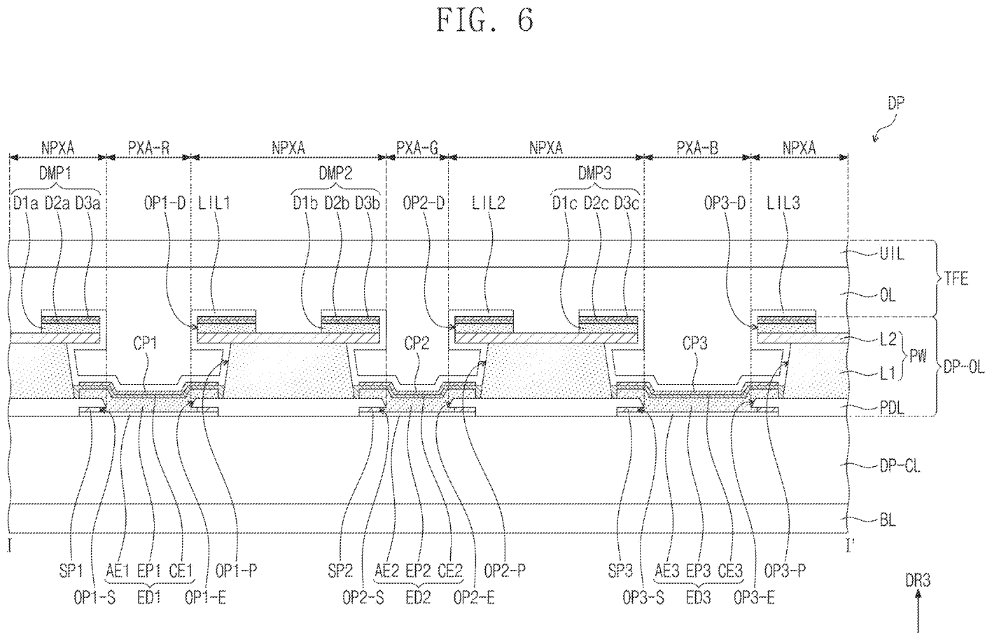

Referring to FIG. 4, the display region DA may include the first to third emissive regions PXA-R, PXA-G, and PXA-B, and a peripheral region NPXA surrounding/among the first to third emissive regions PXA-R, PXA-G, and PXA-B. The first to third emissive regions PXA-R, PXA-G, and PXA-B may correspond to regions through which light provided from light-emitting elements ED1, ED2, and ED3 (refer to FIG. 6) is emitted. The first to third emissive regions PXA-R, PXA-G, and PXA-B may be distinguished from one another depending on the colors of light emitted toward the outside of the display module DM (refer to FIG. 2).

The first to third emissive regions PXA-R, PXA-G, and PXA-B may provide first color light, second color light, and third color light that have different colors, respectively. For example, the first color light may be red light, the second color light may be green light, and the third color light may be blue light. However, examples of the first color light, the second color light, and the third color light are not necessarily limited thereto.

Each of the first to third emissive regions PXA-R, PXA-G, and PXA-B may be defined as a region where an upper surface of an anode is exposed by a light-emitting opening that will be described below. The peripheral region NPXA may set the boundaries between the first to third emissive regions PXA-R, PXA-G, and PXA-B, and may reduce or prevent color mixing between the first to third emissive regions PXA-R, PXA-G, and PXA-B.

A plurality of first emissive regions PXA-R, a plurality of second emissive regions PXA-G, and a plurality of third emissive regions PXA-B may be provided. The plurality of first emissive regions PXA-R, the plurality of second emissive regions PXA-G, and the plurality of third emissive regions PXA-B may have an arrangement (e.g., predetermined arrangement) in the display region DA, and may be repeatedly located. For example, the first and third emissive regions PXA-R and PXA-B may be alternately arranged in the first direction DR1 to form a “first group”. The second emissive regions PXA-G may be arranged in the first direction DR1 to form a “second group”. The “first group” and the “second group” may be provided in plural numbers, and the “first groups” and the “second groups” may be alternately arranged in the second direction DR2.

One second emissive region PXA-G may be spaced apart from one first emissive region PXA-R or one third emissive region PXA-B in a fourth direction DR4. The fourth direction DR4 may be defined as a direction between the first direction DR1 and the second direction DR2.

Meanwhile, FIG. 4 illustrates an arrangement of the first to third emissive regions PXA-R, PXA-G, and PXA-B, and without being limited thereto, the first to third emissive regions PXA-R, PXA-G, and PXA-B may be arranged in various forms. In one or more embodiments, the first to third emissive regions PXA-R, PXA-G, and PXA-B may have a PENTILE™ arrangement form as illustrated in FIG. 4, or, alternatively, the first to third emissive regions PXA-R, PXA-G, and PXA-B may have a stripe arrangement form or a Diamond Pixel™ arrangement form (Diamond Pixel™ and PENTILE™ being registered trademarks of Samsung Display Co., Ltd., Republic of Korea).

The first to third emissive regions PXA-R, PXA-G, and PXA-B may have various shapes on the plane. For example, the first to third emissive regions PXA-R, PXA-G, and PXA-B may have a polygonal, circular, or oval shape. FIG. 4 illustrates the first and third emissive regions PXA-R and PXA-B having a quadrangular shape (or, a rhombic shape) on the plane and the second emissive region PXA-G having an octagonal shape on the plane.

The first to third emissive regions PXA-R, PXA-G, and PXA-B may have the same shape on the plane, or at least some of the first to third emissive regions PXA-R, PXA-G, and PXA-B may have different shapes. FIG. 4 illustrates the first and third emissive regions PXA-R and PXA-B having the same shape on the plane, and the second emissive region PXA-G having a shape different from those of the first and third emissive regions PXA-R and PXA-B.

At least some of the first to third emissive regions PXA-R, PXA-G, and PXA-B may have different areas on the plane. In one or more embodiments, the area of the first emissive region PXA-R emitting red light may be greater than the area of the second emissive region PXA-G emitting green light, and may be smaller than the area of the third emissive region PXA-B emitting blue light. However, the relative size relationship between the first to third emissive regions PXA-R, PXA-G, and PXA-B depending on emission colors is not limited thereto, and may vary depending on the design of the display module DM (refer to FIG. 2). Furthermore, without being limited thereto, the first to third emissive regions PXA-R, PXA-G, and PXA-B may have the same area on the plane.

Meanwhile, the shapes, areas, and arrangement of the first to third emissive regions PXA-R, PXA-G, and PXA-B of the display module DM (refer to FIG. 2) of the present disclosure may be diversely designed depending on the colors of emitted light, the size, and/or configuration of the display module DM (refer to FIG. 2) and are not limited to the one or more embodiments corresponding to FIG. 4.

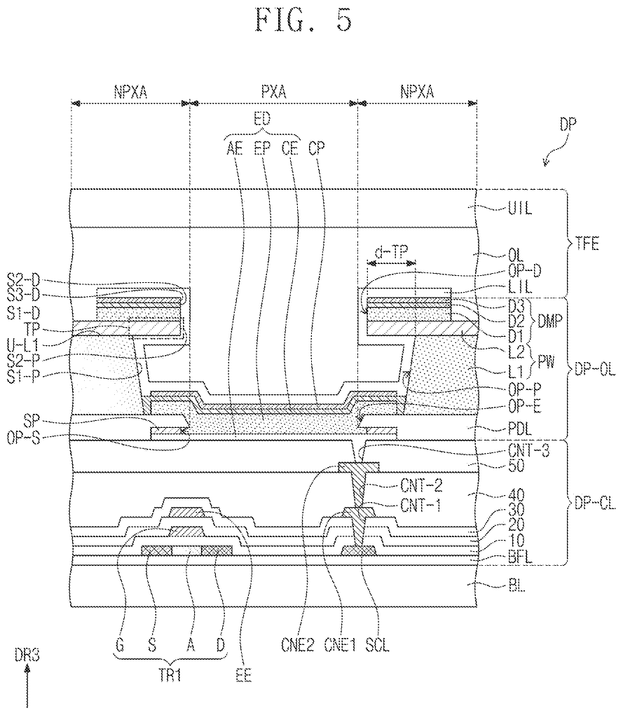

FIG. 5 is a sectional view of the display panel according to one or more embodiments of the present disclosure. In describing FIG. 5, the description will be made with reference to FIG. 2, and descriptions of the same reference numerals will be omitted.

FIG. 5 is a blowup of one emissive region PXA in the display region DA (refer to FIG. 4), and the emissive region PXA of FIG. 5 may correspond to one of the first, second, or third emissive regions PXA-R, PXA-G, or PXA-B of FIG. 4.

Referring to FIG. 5, the display panel DP may include the base layer BL, the circuit element layer DP-CL, the display element layer DP-OL, and the thin film encapsulation layer TFE.

The display panel DP may include a plurality of insulating layers, a semiconductor pattern, a conductive pattern, and a signal line. An insulating layer, a semiconductor layer, and a conductive layer are formed by coating, deposition, or the like. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-OL may be formed by the above-described method.

The circuit element layer DP-CL may be located on the base layer BL. The circuit element layer DP-CL may include a buffer layer BFL, a transistor TR1, a signal transmission region SCL, first to fifth insulating layers 10, 20, 30, 40, and 50, an upper electrode EE, and a plurality of connecting electrodes CNE1 and CNE2.

The buffer layer BFL may be located on the base layer BL. The buffer layer BFL may improve a coupling force between the base layer BL and a semiconductor pattern. The buffer layer BFL may include silicon oxide layers and silicon nitride layers. The silicon oxide layers and the silicon nitride layers may be alternately stacked one above another.

The semiconductor pattern may be located on the buffer layer BFL. The semiconductor pattern may include poly-silicon. However, without being limited thereto, the semiconductor pattern may include amorphous silicon or metal oxide. In FIG. 5, a portion of the semiconductor pattern is illustrated as an example, and the semiconductor pattern may be additionally located in the plurality of emissive regions PXA-R, PXA-G, PXA-B (refer to FIG. 4). The semiconductor pattern may be arranged across the plurality of emissive regions PXA-R, PXA-G, PXA-B according to a specific rule. The semiconductor pattern may have different electrical properties depending on whether the semiconductor pattern is doped or not. The semiconductor pattern may include a first region having a high doping concentration and a second region having a low doping concentration. The first region may be doped with an N-type dopant or a P-type dopant. A P-type transistor may include a first region doped with a P-type dopant.

The first region has a higher conductivity than the second region and substantially serves as an electrode or a signal line. The second region may substantially correspond to an active (or, channel) region of a transistor. In other words, one portion of the semiconductor pattern may be the active region of the transistor, another portion may be a source or drain of the transistor, and another portion may be a conductive region.

A source S, an active region A, and a drain D of the transistor TR1 may be formed from the semiconductor pattern. FIG. 5 illustrates a portion of the signal transmission region SCL formed from the semiconductor pattern. In one or more embodiments, the signal transmission region SCL may be connected to the drain D of the transistor TR1 on the plane.

The first to fifth insulating layers 10, 20, 30, 40, and 50 may be located on the buffer layer BFL. The first to fifth insulating layers 10, 20, 30, 40, and 50 may be inorganic layers or organic layers.

The first insulating layer 10 may be located on (as used herein, “located on” may mean “above”) the buffer layer BFL. The first insulating layer 10 may cover the source S, the active region A, and the drain D of the transistor TR1 and the signal transmission region SCL that are located on the buffer layer BFL. A gate G of the transistor TR1 may be located on the first insulating layer 10. The second insulating layer 20 may be located on the first insulating layer 10 and may cover the gate G. The upper electrode EE may be located on the second insulating layer 20. The third insulating layer 30 may be located on the second insulating layer 20 and may cover the upper electrode EE.

The first connecting electrode CNE1 may be located on the third insulating layer 30. The first connecting electrode CNE1 may be connected to the signal transmission region SCL through a contact hole CNT-1 penetrating the first to third insulating layers 10, 20, and 30. The fourth insulating layer 40 may be located on the third insulating layer 30, and may cover the first connecting electrode CNE1. The fourth insulating layer 40 may be an organic layer.

The second connecting electrode CNE2 may be located on the fourth insulating layer 40. The second connecting electrode CNE2 may be connected to the first connecting electrode CNE1 through a contact hole CNT-2 penetrating the fourth insulating layer 40. The fifth insulating layer 50 may be located on the fourth insulating layer 40, and may cover the second connecting electrode CNE2. The fifth insulating layer 50 may be an organic layer.

The display element layer DP-OL may be located on the circuit element layer DP-CL. The display element layer DP-OL may include a light-emitting element ED, a sacrificial pattern SP, a pixel-defining layer PDL, a barrier wall PW, and dummy patterns DMP.

The light-emitting element ED may include an anode AE (or, a first electrode), an emission pattern EP, and a cathode CE (or, a second electrode). Each of the first to third light-emitting elements ED1, ED2, and ED3 that will be described below may include substantially the same configuration as the light-emitting element ED of FIG. 5. Description of the anode AE, the emission pattern EP, and the cathode CE may be identically applied to an anode, an emission pattern, and a cathode of each of the first to third light-emitting elements that will be described below.

The anode AE may be located on the fifth insulating layer 50 of the circuit element layer DP-CL. The anode AE may be a transmissive electrode, a transflective electrode, or a reflective electrode. The anode AE may be connected to the second connecting electrode CNE2 by a connection contact hole CNT-3 defined to penetrate the fifth insulating layer 50. Accordingly, the anode AE may be electrically connected to the signal transmission region SCL through the first and second connecting electrodes CNE1 and CNE2 and may be electrically connected to a corresponding circuit element. The anode AE may include a single-layer structure or a multi-layer structure. The anode AE may include a plurality of layers including ITO and Ag. For example, the anode AE may include a layer (or, a lower ITO layer) including ITO, a layer (or, an Ag layer) that is located on the lower IOT layer and that includes Ag, and a layer (or, an upper ITO layer) that is located on the Ag layer and that includes ITO.

The sacrificial pattern SP may be located between the anode AE and the pixel-defining layer PDL. The sacrificial pattern SP may correspond to a portion of a layer provided to reduce or prevent damage to the anode AE in a process of forming a barrier wall opening OP-P that will be described below. A sacrificial opening OP-S that exposes a portion of the upper surface of the anode AE may be defined in the sacrificial pattern SP. The sacrificial opening OP-S may overlap a light-emitting opening OP-E that will be described below. The sacrificial pattern SP may include amorphous transparent conductive oxide. For example, the sacrificial pattern SP may be zinc oxide ZnOₓ doped with aluminum (Al).

The pixel-defining layer PDL may be located on the fifth insulating layer 50 of the circuit element layer D-CL. The pixel-defining layer PDL may have the light-emitting opening OP-E defined therein. The light-emitting opening OP-E may correspond to the anode AE, and the pixel-defining layer PDL may expose at least a portion of the anode AE through the light-emitting opening OP-E.

In addition, the light-emitting opening OP-E may correspond to the sacrificial opening OP-S of the sacrificial pattern SP. The upper surface of the anode AE may be spaced apart from the pixel-defining layer DPL (e.g., in the third direction DR3) at the section with the sacrificial pattern SP therebetween. Accordingly, damage to the anode AE in a process of forming the light-emitting opening OP-E may be reduced or prevented.

On the plane, the area of the light-emitting opening OP-E may be smaller than the area of the sacrificial opening OP-S. That is, an inner surface of the pixel-defining layer PDL that defines the light-emitting opening OP-E may be closer to the center of the anode AE than an inner surface of the sacrificial pattern SP that defines the sacrificial opening OP-S. However, without being limited thereto, the inner surface of the sacrificial pattern SP that defines the sacrificial opening OP-S may be substantially aligned with the inner surface of the pixel-defining layer PDL that defines the corresponding light-emitting opening OP-E. In this case, the emissive region PXA may be a region of the anode AE exposed from the corresponding sacrificial opening OP-S.

The pixel-defining layer PDL may include an inorganic insulating material. The pixel-defining layer PDL may include at least one of silicon oxide SiOₓ, silicon nitride SiNₓ, or silicon oxy nitride SiOₓN_{y}. For example, the pixel-defining layer PDL may include silicon nitride SiNₓ. The pixel-defining layer PDL may be located between the anode AE and the barrier wall PW and may block electrical connection between the anode AE and the barrier wall PW. However, without being limited thereto, the pixel-defining layer PDL may include an organic insulating material. Furthermore, the pixel-defining layer PDL may be implemented with a single layer, or may be implemented with a plurality of layers. When the pixel-defining layer PDL is implemented with a plurality of layers, the plurality of layers may include different materials.

The barrier wall PW may be located on the pixel-defining layer PDL. The barrier wall PW may have the barrier wall opening OP-P defined therein. The barrier wall opening OP-P may correspond to the light-emitting opening OP-E and may expose at least a portion of the anode AE.

The barrier wall PW may have an undercut shape on the cross section. The barrier wall PW may include multiple layers sequentially stacked one above another, and at least one layer among the multiple layers may be recessed when compared to the other layers. At least one layer among the multiple layers included in the barrier wall PW may protrude when compared to the other layers. Accordingly, the barrier wall PW may include a tip portion TP.

The barrier wall PW may include a first barrier wall layer L1 and a second barrier wall layer L2. The first barrier wall layer L1 may be located on the pixel-defining layer PDL, and the second barrier wall layer L2 may be located on the first barrier wall layer L1. Based on the emissive region PXA, the first barrier wall layer L1 may be relatively recessed when compared to the second barrier wall layer L2. That is, the first barrier wall layer L1 may be undercut with respect to the second barrier wall layer L2.

Meanwhile, only the state in which the first barrier wall layer L1 and the second barrier wall layer L2 are located is illustrated in the drawing. However, without being limited thereto, a third barrier wall layer may be additionally located on the second barrier wall layer L2, or may be additionally located under the first barrier wall layer L1, and the barrier wall PW is not limited.

The first barrier wall layer L1 may have conductivity. The first barrier wall layer L1 may include a conductive material. For example, the conductive material may include metal, metal nitride, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The metal nitride may include titanium nitride (TiN). The transparent conductive oxide may include indium tin oxide (ITO), indium zinc oxide (IZO), zinc oxide, indium oxide, indium gallium oxide, indium gallium zinc oxide (IGZO), or aluminum zinc oxide.

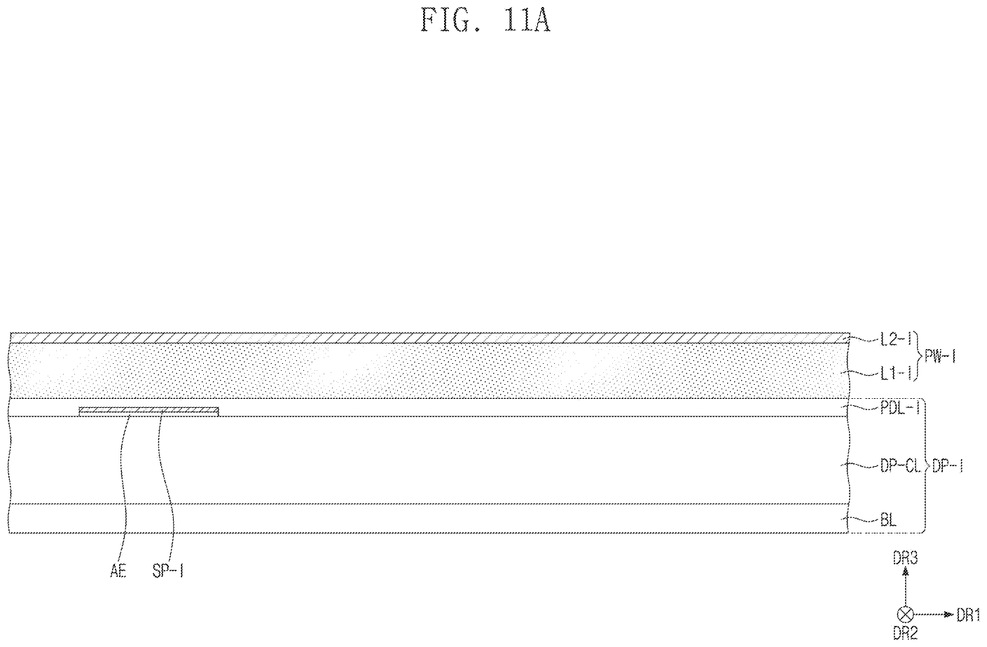

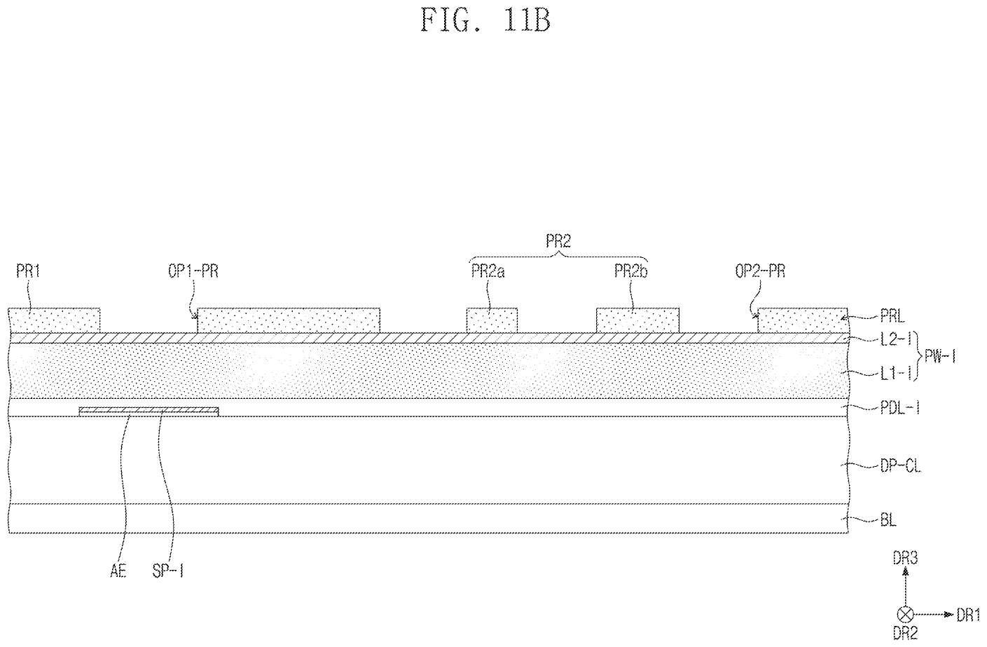

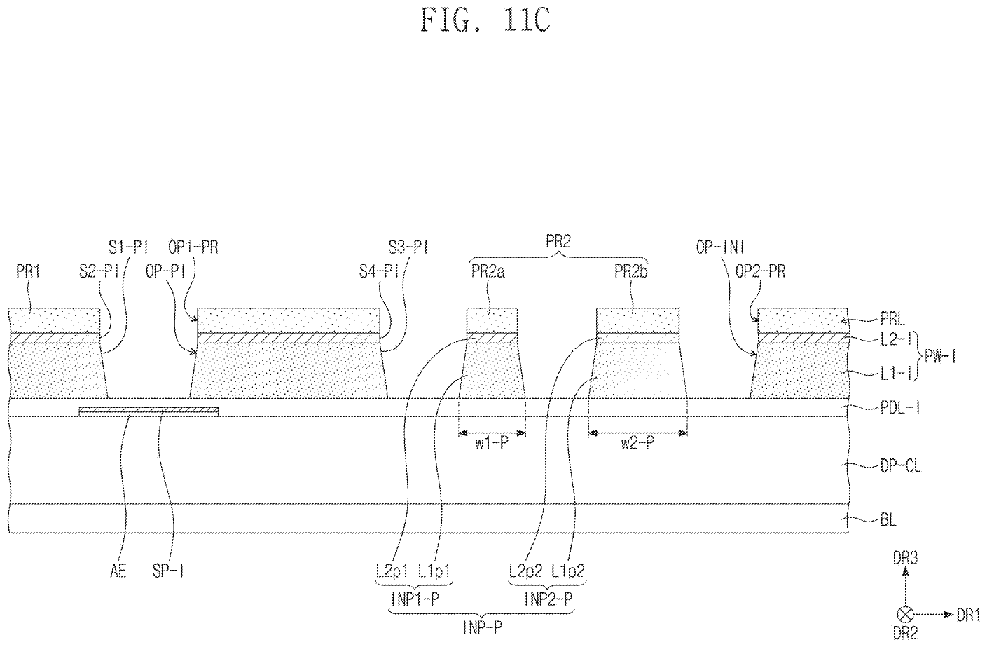

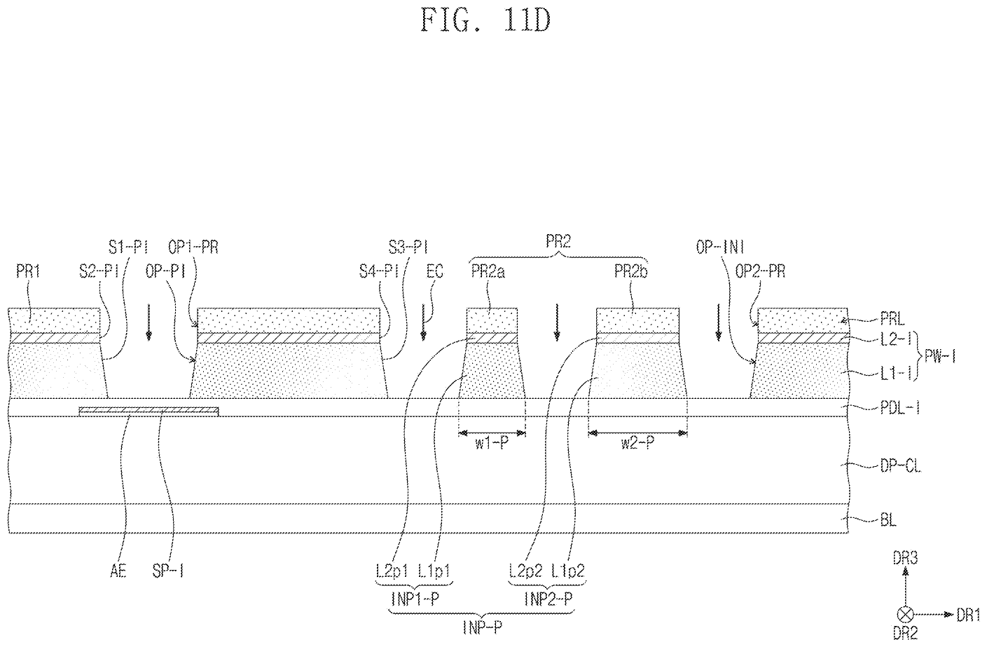

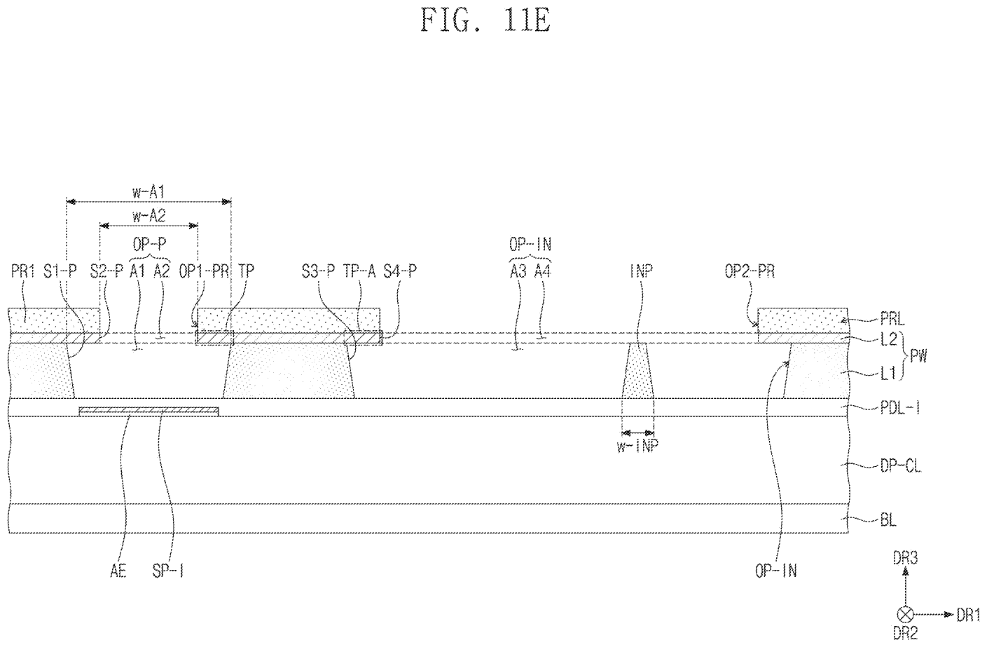

The second barrier wall layer L2 is located on the first barrier wall layer L1. The second barrier wall layer L2 may include a material having etch selectivity with respect to the first barrier wall layer L1. For example, the reactivity of the second barrier wall layer L2 with a chemical EC (refer to FIG. 11D), as will be described below, may be lower than the reactivity of the first barrier wall layer L1 with the chemical EC. When compared to the second barrier wall layer L2, the first barrier wall layer L1 may be relatively recessed with respect to the emissive region PXA. The second barrier wall layer L2 may define the tip portion TP formed in the barrier wall PW.

The tip portion TP of the barrier wall PW may be defined as a portion of the second barrier wall layer L2 that protrudes from the first barrier wall layer L1 toward the emissive region PXA. The length, or width, d-TP of the tip portion TP may be defined as the length of the portion of the second barrier wall layer L2 that protrudes from an upper surface U-L1 of the first barrier wall layer L1 toward the emissive region PXA. The upper surface of the second barrier wall layer L2 may form the uppermost surface of the barrier wall PW, and may define the upper surface of the tip portion TP formed in the barrier wall PW.

In one or more embodiments, the second barrier wall layer L2 may include a conductive material. For example, the conductive material may include metal, metal nitride, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The metal nitride may include titanium nitride (TIN). The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Alternatively, in one or more embodiments of the present disclosure, the second barrier wall layer L2 may include an insulating material. For example, the second barrier wall layer L2 may include an inorganic insulating material, and may include a silicon-based compound. For example, the second barrier wall layer L2 may include at least one of silicon oxide SiOₓ, silicon nitride SiNₓ, or silicon oxy nitride SiOₓN_{y}.

The barrier wall opening OP-P defined in the barrier wall PW may include a first region A1 (refer to FIG. 11E) and a second region A2 (refer to FIG. 11E). The first barrier wall layer L1 may include a first inner surface S1-P that defines the first region A1 (refer to FIG. 11E) of the barrier wall opening OP-P. The second barrier wall layer L2 may include a second inner surface S2-P that defines the second region A2 (refer to FIG. 11E) of the barrier wall opening OP-P.

The first inner surface S1-P of the first barrier wall layer L1 may be recessed inwardly when compared to the second inner surface S2-P of the second barrier wall layer L2. On the plane, the second inner surface S2-P of the second barrier wall layer L2 that defines the second region A2 (refer to FIG. 11E) may protrude further than the first inner surface S1-P of the first barrier wall layer L1 that defines the first region A1 (refer to FIG. 11E), and may be closer to overlapping the center of the anode AE than the first inner surface S1-P. The first region A1 (refer to FIG. 11E) may have a width that is different from the width of the second region A2 (refer to FIG. 11E). The width of the second region A2 (refer to FIG. 11E) may be narrower than the width of the first region A1 (refer to FIG. 11E).

Meanwhile, although FIG. 5 illustrates an example that the first inner surface S1-P of the first barrier wall layer L1 has a tapered shape with respect to the upper surface of the pixel-defining layer PDL, the present disclosure is not limited thereto. For example, the first inner surface S1-P may have a vertically extending sidewall, or may have an inverted tapered shape. Furthermore, although FIG. 5 illustrates an example that the second inner surface S2-P of the second barrier wall layer L2 vertically extends with respect to the upper surface of the pixel-defining layer PDL, the present disclosure is not limited thereto. For example, the second inner surface S2-P may have a tapered shape, or an inverted tapered shape, with respect to the upper surface of the pixel-defining layer PDL.

The emission pattern EP may be located on the anode AE. The emission pattern EP may include an emissive layer including a luminescent material. The emission pattern EP may further include a hole injection layer (HIL) and a hole transport layer (HTL) that are located between the anode AE and the emissive layer, and may further include an electron transport layer (ETL) and an electron injection layer (EIL) that are located on the emissive layer. The emission pattern EP may be referred to as the “organic layer” or the “intermediate layer”.

The emission pattern EP may be subjected to patterning by the tip portion defined in the barrier wall PW. The emission pattern EP may be located in the sacrificial opening OP-S, the light-emitting opening OP-E, and the barrier wall opening OP-P. The emission pattern EP may cover a portion of the upper surface of the pixel-defining layer PDL exposed from the barrier wall opening OP-P.

The cathode CE may be located on the emission pattern EP. The cathode CE may be subjected to patterning by the tip portion defined in the barrier wall PW. The cathode CE may contact the first inner surface S1-P of the first barrier wall layer L1.

The barrier wall PW may receive a bias voltage (or, a common voltage). Accordingly, the cathode CE may be electrically connected to the barrier wall PW, and may receive the bias voltage (or, the common voltage) from the barrier wall PW.

According to one or more embodiments of the present disclosure, the display panel DP may further include a capping pattern CP. The capping pattern CP may be located in the barrier wall opening OP-P, and may be located on the cathode CE. The capping pattern CP may be subjected to patterning by the tip portion formed in the barrier wall PW.

Although FIG. 5 illustrates an example that the capping pattern CP does not contact the second inner surface S2-P of the second barrier wall layer L2, the present disclosure is not limited thereto. For example, the capping pattern CP may be formed to contact the second inner surface S2-P of the second barrier wall layer L2.

Meanwhile, according to one or more embodiments of the present disclosure, the capping pattern CP may be omitted.

The dummy patterns DMP may be located on the barrier wall PW. The dummy patterns DMP may include a first layer dummy pattern D1, a second layer dummy pattern D2, and a third layer dummy pattern D3. The first to third layer dummy patterns D1, D2, and D3 may be sequentially stacked on the upper surface of the second barrier wall layer L2 of the barrier wall PW in the third direction DR3.

The first layer dummy pattern D1 may include an organic material. For example, the first layer dummy pattern D1 may include the same material as the emission pattern EP. The first layer dummy pattern D1 may be concurrently or substantially simultaneously formed with the emission pattern EP through one process, and may be separated from the emission pattern EP by the undercut shape of the barrier wall PW.

The second layer dummy pattern D2 may include a conductive material. For example, the second layer dummy pattern D2 may include the same material as the cathode CE. The second layer dummy pattern D2 may be concurrently or substantially simultaneously formed with the cathode CE through one process, and may be separated from the cathode CE by the undercut shape of the barrier wall PW.

The third layer dummy pattern D3 may include the same material as the capping pattern CP. The third layer dummy pattern D3 may be concurrently or substantially simultaneously formed with the capping pattern CP through one process, and may be separated from the capping pattern CP by the undercut shape of the barrier wall PW.

A dummy opening OP-D may be defined in the dummy patterns DMP. The dummy opening OP-D may overlap the light-emitting opening OP-E. The dummy opening OP-D may include a region (hereinafter, referred to as the first dummy region) defined by an inner surface of the first layer dummy pattern D1, a region (hereinafter, referred to as the second dummy region) defined by an inner surface of the second layer dummy pattern D2, and a region (hereinafter, referred to as the third dummy region) defined by an inner surface of the third layer dummy pattern D3. On the plane, each of the first to third layer dummy patterns D1, D2, and D3 may have a closed-line shape surrounding the emissive region PXA.

Although FIG. 5 illustrates one example that the inner surfaces of the first to third layer dummy patterns D1, D2, and D3 are aligned with the second inner surface S2-P of the second barrier wall layer L2, the present disclosure is not limited thereto, and the first to third layer dummy patterns D1, D2, and D3 may cover the second inner surface S2-P of the second barrier wall layer L2.

The thin film encapsulation layer TFE may be located on the display element layer DP-OL. The thin film encapsulation layer TFE may include a lower inorganic encapsulation pattern LIL, an organic encapsulation film OL, and an upper inorganic encapsulation film UIL.

The lower inorganic encapsulation pattern LIL may be located to overlap the light-emitting opening OP-E. The lower inorganic encapsulation pattern LIL may cover the light-emitting element ED and the dummy patterns DMP, and a portion of the lower inorganic encapsulation pattern LIL may be located in the barrier wall opening OP-P. According to one or more embodiments, the lower inorganic encapsulation pattern LIL may contact the first inner surface S1-P of the first barrier wall layer L1 and the second inner surface S2-P of the second barrier wall layer L2.

The organic encapsulation film OL may cover the lower inorganic encapsulation pattern LIL and may provide a flat upper surface. The upper inorganic encapsulation film UIL may be located on the organic encapsulation film OL.

The lower inorganic encapsulation pattern LIL and the upper inorganic encapsulation film UIL may protect the display element layer DP-OL from moisture/oxygen, and the organic encapsulation film OL may protect the display element layer DP-OL from foreign matter, such as dust particles.

FIG. 6 is a sectional view of the display panel according to one or more embodiments of the present disclosure. FIG. 6 is a sectional view taken along the line I-I′ of FIG. 4. FIG. 6 is an enlarged view illustrating one first emissive region PXA-R, one second emissive region PXA-G, and one third emissive region PXA-B, and the description of the emissive region PXA of FIG. 5 may be identically applied to each of the first to third emissive regions PXA-R, PXA-G, and PXA-B.

Referring to FIG. 6, the display panel DP may include the base layer BL, the circuit element layer DP-CL, the display element layer DP-OL, and the thin film encapsulation layer TFE. The display element layer DP-OL may include the light-emitting elements ED1, ED2, and ED3, sacrificial patterns SP1, SP2, and SP3, the pixel-defining layer PDL, the barrier wall PW, and dummy patterns DMP1, DMP2, and DMP3.

The light-emitting elements ED1, ED2, and ED3 may include the first light-emitting element ED1, the second light-emitting element ED2, and the third light-emitting element ED3. The first light-emitting element ED1 may include a first anode AE1, a first emission pattern EP1, and a first cathode CE1. The second light-emitting element ED2 may include a second anode AE2, a second emission pattern EP2, and a second cathode CE2. The third light-emitting element ED3 may include a third anode AE3, a third emission pattern EP3, and a third cathode CE3. The first to third anodes AE1, AE2, and AE3 may be provided in a plurality of patterns. In one or more embodiments, the first emission pattern EP1 may provide red light, the second emission pattern EP2 may provide green light, and the third emission pattern EP3 may provide blue light.

First to third light-emitting openings OP1-E, OP2-E, and OP3-E may be defined in the pixel-defining layer PDL. The first light-emitting opening OP1-E may expose at least a portion of the first anode AE1. The first emissive region PXA-R may be defined as a region of the upper surface of the first anode AE1 exposed by the first light-emitting opening OP1-E. The second light-emitting opening OP2-E may expose at least a portion of the second anode AE2. The second emissive region PXA-G may be defined as a region of the upper surface of the second anode AE2 exposed by the second light-emitting opening OP2-E. The third light-emitting opening OP3-E may expose at least a portion of the third anode AE3. The third emissive region PXA-B may be defined as a region of the upper surface of the third anode AE3 exposed by the third light-emitting opening OP3-E.

The sacrificial patterns SP1, SP2, and SP3 may include the first sacrificial pattern SP1, the second sacrificial pattern SP2, and the third sacrificial pattern SP3. The first to third sacrificial patterns SP1, SP2, and SP3 may be located on the upper surfaces of the first to third anodes AE1, AE2, and AE3, respectively. First to third sacrificial openings OP1-S, OP2-S, and OP3-S corresponding to the first to third light-emitting openings OP1-E, OP2-E, and OP3-E may be defined in the first to third sacrificial patterns SP1, SP2, and SP3, respectively.

First to third barrier wall openings OP1-P, OP2-P, and OP3-P corresponding to the first to third light-emitting openings OP1-E, OP2-E, and OP3-E, respectively, may be defined in the barrier wall PW.

Each of the first to third barrier wall openings OP1-P, OP2-P, and OP3-P may include the first region A1 (refer to FIG. 11E) and the second region A2 (refer to FIG. 11E) mentioned above with reference to FIG. 5. The first barrier wall layer L1 may include the first inner surfaces S1-P (refer to FIG. 5) that define portions of the first regions A1 of the first to third barrier wall openings OP1-P, OP2-P, and OP3-P. The second barrier wall layer L2 may include the second inner surfaces S2-P (refer to FIG. 5) that define the second regions A2 of the first to third barrier wall openings OP1-P, OP2-P, and OP3-P.

The first emission pattern EP1 and the first cathode CE1 may be located in the first barrier wall opening OP1-P, the second emission pattern EP2 and the second cathode CE2 may be located in the second barrier wall opening OP2-P, and the third emission pattern EP3 and the third cathode CE3 may be located in the third barrier wall opening OP3-P. The first to third cathodes CE1, CE2, and CE3 may contact the first inner surfaces S1-P (see FIG. 5) of the first barrier wall layer L1, respectively.

The first to third cathodes CE1, CE2, and CE3 may be physically separated by the second barrier wall layer L2 that forms tip portions TP, and may be formed in the respective light-emitting openings OP1-E, OP2-E, and OP3-E. The first to third cathodes CE1, CE2, and CE3 may contact the first barrier wall layer L1, and may be electrically connected together to receive the common voltage. The first barrier wall layer L1 in contact with the first to third cathodes CE1, CE2, and CE3 may have a higher electrical conductivity than the second barrier wall layer L2, and thus may decrease contact resistance with the first to third cathodes CE1, CE2, and CE3. Accordingly, a common cathode voltage may be uniformly provided for the emissive regions PXA-R, PXA-G, and PXA-B.

According to the present disclosure, the plurality of emission patterns EP1, EP2, and EP3 may be subjected to patterning, and may be deposited in pixel units by the tip portions defined in the barrier wall PW. That is, the plurality of emission patterns EP1, EP2, and EP3 may be commonly formed by using an open mask, but may be suitably divided in pixel units by the barrier wall PW.

In contrast, when the plurality of emission patterns EP1, EP2, and EP3 are subjected to patterning by using a fine metal mask (FMM), a spacer for support that protrudes from a conductive barrier wall has to be provided to support the fine metal mask. Furthermore, the fine metal mask may be spaced, by the height of the barrier wall and the spacer, apart from a base surface on which patterning is performed, and therefore there may be a limitation in the implementation of high resolution. In addition, because the fine metal mask is brought into contact with the spacer, foreign matter may remain on the spacer after the patterning process of the plurality of emission patterns EP1, EP2, and EP3, or the spacer may be damaged by a dent defect of the fine metal mask. Accordingly, a defective display panel may be formed.

Because the barrier wall PW is included, the physical separation between the light-emitting elements ED1, ED2, and ED3 may be suitably achieved. Accordingly, current leakage or a driving error between the adjacent emissive regions PXA-R, PXA-G, and PXA-B may be reduced or prevented, and the light-emitting elements ED1, ED2, and ED3 may be independently driven.

For example, the plurality of emission patterns EP1, EP2, and EP3 may be subjected to patterning without a mask in contact with an internal component in the display region DA (refer to FIG. 1b). Accordingly, a defect rate may be reduced, and thus the process reliability of the display panel DP may be improved. Because patterning is possible even though a separate spacer for support that protrudes from the barrier wall PW is not provided, the areas of the emissive regions PXA-R, PXA-G, and PXA-B may be scaled down, and thus the display panel DP capable of suitably implementing high resolution may be provided.

Furthermore, in the manufacture of the large-area display panel DP, the manufacture of a large-area mask may be omitted. Accordingly, process costs may be reduced, and the display panel DP may not be affected by defects that are likely to occur in the large-area mask. Thus, the process reliability of the display panel DP may be improved.

Capping patterns CP1, CP2, and CP3 may include the first capping pattern CP1, the second capping pattern CP2, and the third capping pattern CP3. The first to third capping patterns CP1, CP2, and CP3 may be located on the first to third cathodes CE1, CE2, and CE3, respectively, and may be located in the first to third barrier wall openings OP1-P, OP2-P, and OP3-P, respectively.

The dummy patterns DMP1, DMP2, and DMP3 may include the first dummy patterns DMP1, the second dummy patterns DMP2, and the third dummy patterns DMP3. The first dummy patterns DMP1 may include a first layer dummy pattern D1a, a second layer dummy pattern D2a, and a third layer dummy pattern D3a. The second dummy patterns DMP2 may include a first layer dummy pattern D1b, a second layer dummy pattern D2b, and a third layer dummy pattern D3b. The third dummy patterns DMP3 may include a first layer dummy pattern D1c, a second layer dummy pattern D2c, and a third layer dummy pattern D3c.

The first dummy patterns DMP1 may include the 1-1, 2-1, and 3-1 layer dummy patterns D1a, D2a, and D3a surrounding the first emissive region PXA-R on the plane. The 1-1 layer dummy pattern D1a may include the same material as the first emission pattern EP1 and may be formed through the same process as that of the first emission pattern EP1. The 2-1 layer dummy pattern D2a may include the same material as the first cathode CE1 and may be formed through the same process as that of the first cathode CE1. The 3-1 layer dummy pattern D3a may include the same material as the first capping pattern CP1 and may be formed through the same process as that of the first capping pattern CP1.

The second dummy patterns DMP2 may include the 1-2, 2-2, and 3-2 layer dummy patterns D1b, D2b, and D3b surrounding the second emissive region PXA-G on the plane. The 1-2 layer dummy pattern D1b may include the same material as the second emission pattern EP2 and may be formed through the same process as that of the second emission pattern EP2. The 2-2 layer dummy pattern D2b may include the same material as the second cathode CE2 and may be formed through the same process as that of the second cathode CE2. The 3-2 layer dummy pattern D3b may include the same material as the second capping pattern CP2 and may be formed through the same process as that of the second capping pattern CP2.

The third dummy patterns DMP3 may include the 1-3, 2-3, and 3-3 layer dummy patterns D1c, D2c, and D3c surrounding the third emissive region PXA-B on the plane. The 1-3 layer dummy pattern D1c may include the same material as the third emission pattern EP3 and may be formed through the same process as that of the third emission pattern EP3. The 2-3 layer dummy pattern D2c may include the same material as the third cathode CE3 and may be formed through the same process as that of the third cathode CE3. The 3-3 layer dummy pattern D3c may include the same material as the third capping pattern CP3 and may be formed through the same process as that of the third capping pattern CP3.

First to third dummy openings OP1-D, OP2-D, and OP3-D overlapping the first to third light-emitting openings OP1-E, OP2-E, and OP3-E may be defined in the dummy patterns DMP1, DMP2, and DMP3, respectively. The first dummy opening OP1-D may be defined by inner surfaces of the 1-1, 2-1, and 3-1 layer dummy patterns D1a, D2a, and D3a, the second dummy opening OP2-D may be defined by inner surfaces of the 1-2, 2-2, and 3-2 layer dummy patterns D1b, D2b, and D3b, and the third dummy opening OP3-D may be defined by inner surfaces of the 1-3, 2-3, and 3-3 layer dummy patterns D1c, D2c, and D3c.

The thin film encapsulation layer TFE may include lower inorganic encapsulation patterns LIL1, LIL2, and LIL3, the organic encapsulation film OL, and the upper inorganic encapsulation film UIL. In this embodiments, the lower inorganic encapsulation patterns LIL1, LIL2, and LIL3 may include the first lower inorganic encapsulation pattern LIL1, the second lower inorganic encapsulation pattern LIL2, and the third lower inorganic encapsulation pattern LIL3. The first to third lower inorganic encapsulation patterns LIL1, LIL2, and LIL3 may correspond to the first to third light-emitting openings OP1-E, OP2-E, and OP3-E, respectively.

The first lower inorganic encapsulation pattern LIL1 may cover the first light-emitting element ED1, the 1-1 layer dummy pattern D1a, the 2-1 layer dummy pattern D2a, and the 3-1 layer dummy pattern D3a and may be partially located in the first barrier opening OP1-P. The second lower inorganic encapsulation pattern LIL2 may cover the second light-emitting element ED2, the 1-2 layer dummy pattern D1b, the 2-2 layer dummy pattern D2b, and the 3-2 layer dummy pattern D3b and may be partially located in the second barrier opening OP2-P. The third lower inorganic encapsulation pattern LIL3 may cover the third light-emitting element ED3, the 1-3 layer dummy pattern D1c, the 2-3 layer dummy pattern D2c, and the 3-3 layer dummy pattern D3c and may be partially located in the third barrier opening OP3-P. The first to third lower inorganic encapsulation patterns LIL1, LIL2, and LIL3 may be provided in pattern forms spaced apart from each other.

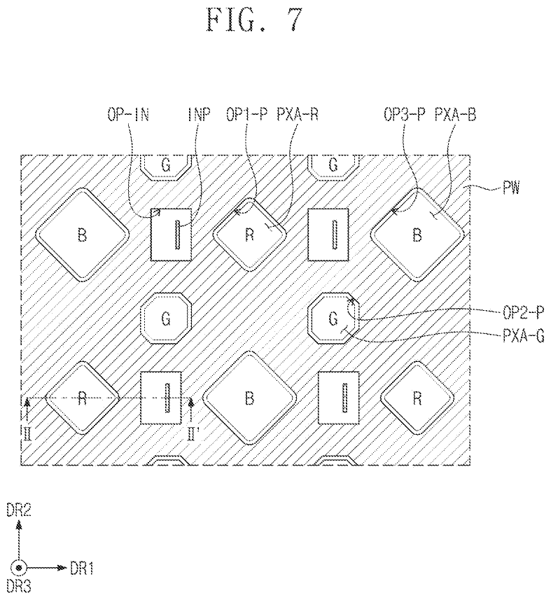

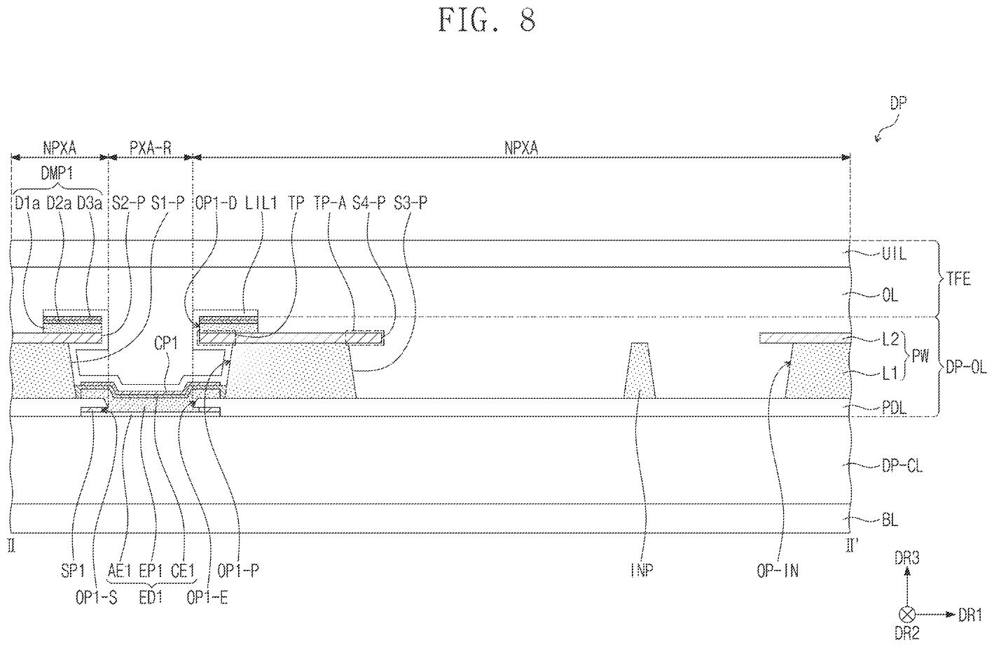

FIG. 7 is an enlarged plan view illustrating some components of the display panel according to one or more embodiments of the present disclosure. FIG. 8 is a sectional view of the display panel taken along the line II-II′ of FIG. 7 according to one or more embodiments of the present disclosure. FIG. 7 is a plan view illustrating the barrier wall PW, and for convenience of description, the first to third emissive regions PXA-R, PXA-G, and PXA-B are illustrated together.

Referring to FIGS. 7 and 8, the barrier wall openings OP1-P, OP2-P, and OP3-P and an inspection opening OP-IN may be defined in the barrier wall PW. The inspection opening OP-IN may be additionally defined in the barrier wall PW. The barrier wall openings OP1-P, OP2-P, and OP3-P may include the first barrier wall opening OP1-P overlapping the first emissive region PXA-R, the second barrier wall opening OP2-P overlapping the second emissive region PXA-G, and the third barrier wall opening OP3-P overlapping the third emissive region PXA-B.

The inspection opening OP-IN may provide a space in which an inspection pattern INP to be described below is located. The inspection opening OP-IN may be spaced apart from the first to third barrier wall openings OP1-P, OP2-P, and OP3-P. The inspection opening OP-IN may not overlap the first to third emissive regions PXA-R, PXA-G, and PXA-B and may overlap the peripheral region NPXA.

In one or more embodiments, a plurality of inspection openings OP-IN may be provided. FIG. 7 illustrates an example that the inspection openings OP-IN are respectively located between the first barrier wall openings OP1-P (or, the first emissive regions PXA-R) and the third barrier wall openings OP3-P (or, the third emissive regions PXA-B). However, the positions of the inspection openings OP-IN are not limited as long as the inspection openings OP-IN are capable of providing spaces for the inspection patterns INP without interference with the barrier wall openings OP1-P, OP2-P, and OP3-P.

Meanwhile, although FIG. 7 illustrates an example that the inspection openings OP-IN have a quadrangular shape on the plane, the shape of the inspection openings OP-IN on the plane is not limited as long as the inspection openings OP-IN are capable of providing spaces for the inspection patterns INP.

The display panel DP may further include the inspection patterns INP. The inspection patterns INP may be located in the inspection openings OP-IN. One inspection pattern INP may be located in one inspection opening OP-IN. The inspection patterns INP may be used to determine whether the tip portions TP of the barrier wall PW are formed to have the length d-TP (refer to FIG. 5) within a suitable range. Detailed description thereabout will be given below.

The inspection patterns INP may have a rectangular shape on the plane. For example, the inspection patterns INP may have a rectangular shape including short sides extending in the first direction DR1 and long sides extending in the second direction DR2 on the plane. However, the extension directions of the long sides and the short sides are not limited thereto.

FIG. 8 is a blowup of a portion of the display panel DP that corresponds to a portion of the barrier wall PW where one first barrier wall opening OP1-P and one inspection opening OP-IN are defined.

The inspection opening OP-IN may include a third region A3 (refer to FIG. 11E) and a fourth region A4 (refer to FIG. 11E). The first barrier wall layer L1 may include a third inner surface S3-P that defines the third region A3 (refer to FIG. 11E) of the inspection opening OP-IN, and the second barrier wall layer L2 may include a fourth inner surface S4-P that defines the fourth region A4 (refer to FIG. 11E) of the inspection opening OP-IN.

In one or more embodiments, the inspection opening OP-IN may be concurrently or substantially simultaneously formed together with at least one of the first, second, or third barrier wall openings OP1-P, OP2-P, or OP3-P. The first to third barrier wall openings OP1-P, OP2-P, and OP3-P may be formed through different etching processes. In this case, the inspection opening OP-IN may be concurrently or substantially simultaneously formed together with one of the first, second, or third barrier wall openings OP1-P, OP2-P, or OP3-P. Alternatively, the first to third barrier wall openings OP1-P, OP2-P, and OP3-P may all be formed through the same etching process. In this case, the inspection opening OP-IN may be concurrently or substantially simultaneously formed together with all of the first to third barrier wall openings OP1-P, OP2-P, and OP3-P.

In one or more embodiments, an additional tip portion TP-A may be defined in the barrier wall PW. The additional tip portion TP-A may be defined as a portion of the second barrier wall layer L2 that protrudes from the first barrier wall layer L1 toward the inspection pattern INP. The third inner surface S3-P of the first barrier wall layer L1 may be recessed inward when compared to the fourth inner surface S4-P of the second barrier wall layer L2. On the plane, the fourth inner surface S4-P may protrude when compared to the third inner surface S3-P, and may be adjacent to the inspection pattern INP on the plane.

However, without being limited thereto, the inspection opening OP-IN may be formed through an etching process that is different from that of the first to third barrier wall openings OP1-P, OP2-P, and OP3-P (refer to FIG. 6). In such a case, the fourth inner surface S4-P might not protrude when compared to the third inner surface S3-P, and the third and fourth inner surfaces S3-P and S4-P may be substantially aligned with each other.

The inspection pattern INP may be located on the pixel-defining layer PDL. The inspection pattern INP may include the same material as the first barrier wall layer L1 of the barrier wall PW. The inspection pattern INP may be formed in a process of forming the first barrier wall layer L1. In one or more embodiments, the inspection pattern INP may have substantially the same height as the first barrier wall layer L1.

The inspection pattern INP may be covered by the thin film encapsulation layer TFE. The inspection pattern INP may contact the organic encapsulation film OL.

The inspection pattern INP may be one initial inspection pattern remaining after an undercut etching process among two or more initial inspection patterns INP-P (refer to FIG. 11C). On the section, the two or more initial inspection patterns INP-P (refer to FIG. 11C) may have different widths in one direction (e.g., the first direction DR1). After the undercut etching process, whether the tip portion TP of the barrier wall PW is formed to have the length d-TP (refer to FIG. 5) within the suitable range may be determined based on whether the initial inspection patterns INP-P (refer to FIG. 11C) are removed and/or remaining. Detailed description thereabout will be given below.

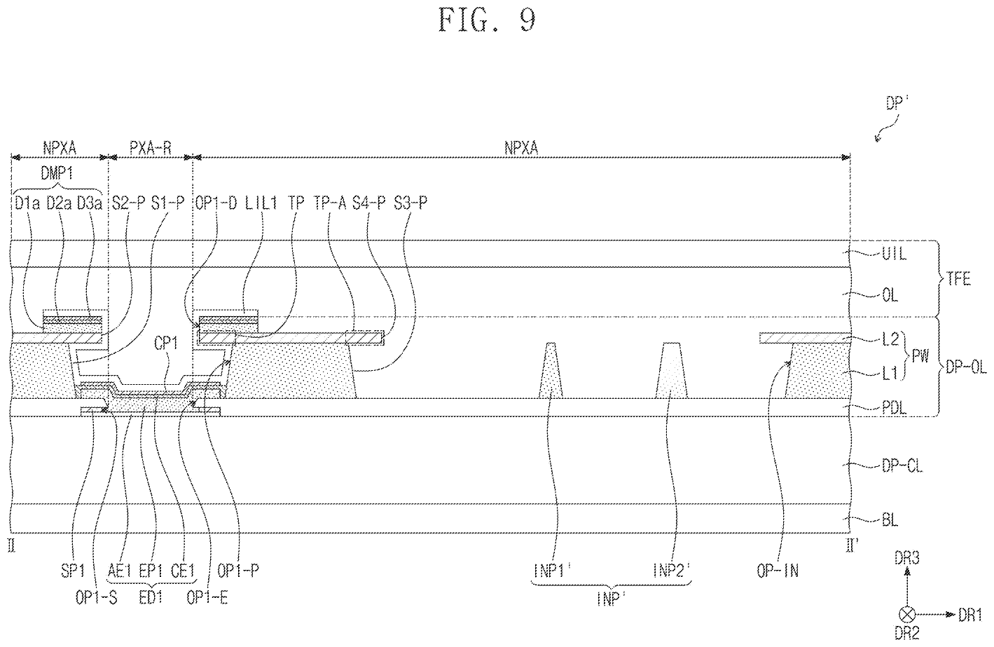

FIG. 9 is a sectional view of the display panel taken along the line II-II′ of FIG. 7 according to one or more embodiments of the present disclosure. In describing FIG. 9, components identical or similar to the components described with reference to FIGS. 1A to 8 will be assigned with identical or similar reference numerals, and repetitive descriptions will be omitted.

Two inspection patterns INP′ may be located in one inspection opening OP-IN. The inspection patterns INP′ may include a first inspection pattern INP1′ and a second inspection pattern INP2′. On the section, the width of the first inspection pattern INP1′ in one direction (e.g., the first direction DR1) may be different from the width of the second inspection pattern INP2′ in the one direction (e.g., the first direction DR1).

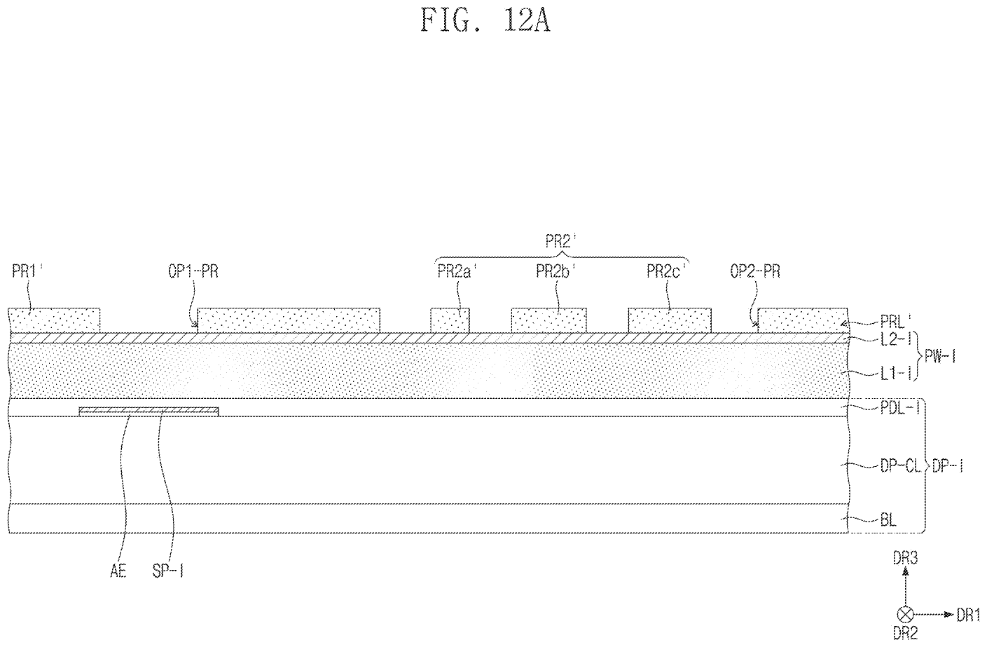

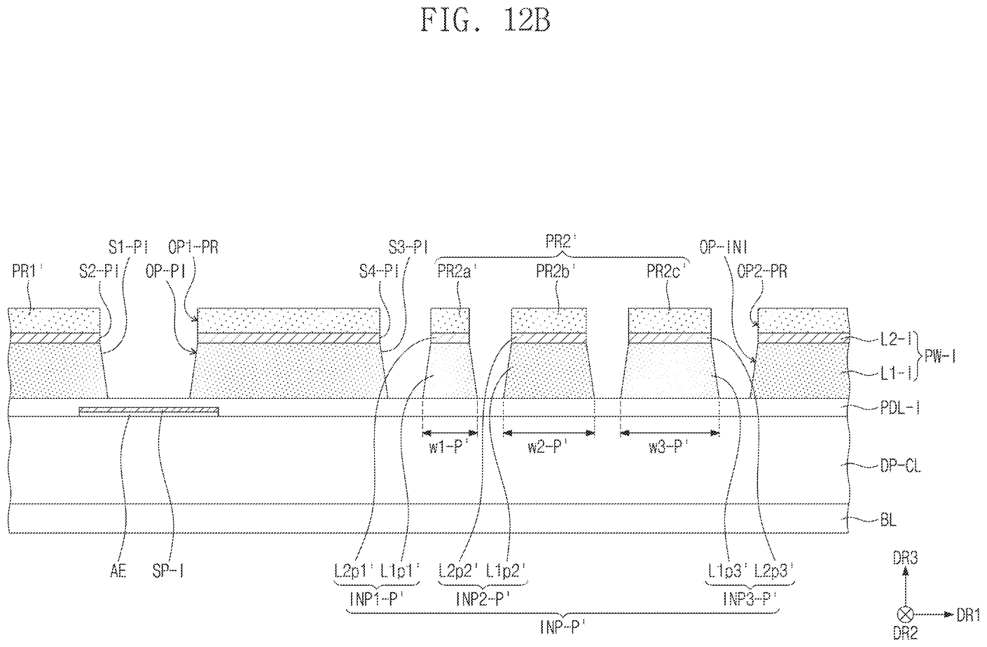

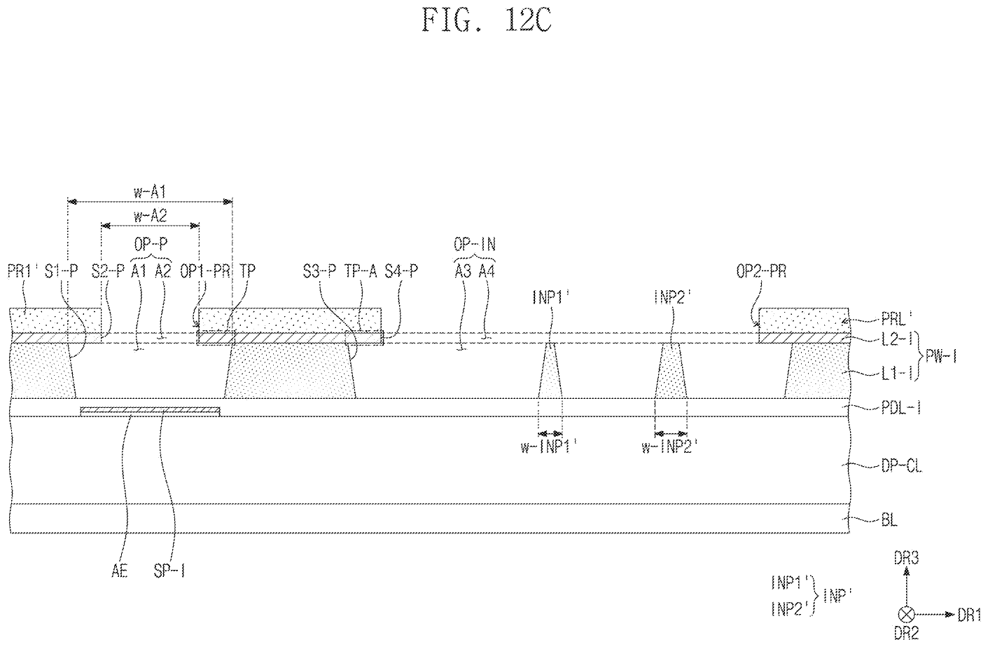

The first and second inspection patterns INP1′ and INP2′ may be two inspection patterns INP′ remaining after an undercut etching process among three or more initial inspection patterns INP-P′ (refer to FIG. 12B). On the section, the three or more initial inspection patterns INP-P′ (refer to FIG. 12B) may have different widths in the one direction (e.g., the first direction DR1). After the undercut etching process, whether the tip portion TP of the barrier wall PW is formed to have the length d-TP (refer to FIG. 5) within the suitable range may be determined based on whether the initial inspection patterns INP-P′ (refer to FIG. 12B) are removed and/or left. Detailed description thereabout will be given below.

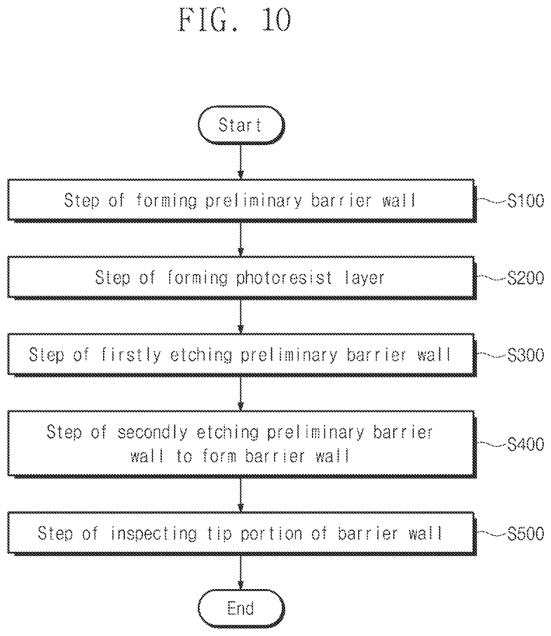

FIG. 10 is a flowchart illustrating a display panel manufacturing method according to one or more embodiments of the present disclosure. FIGS. 11A to 11E are sectional views illustrating some of the operations of the display panel manufacturing method according to one or more embodiments of the present disclosure. In describing FIGS. 11A to 11E, components identical or similar to the components described above with reference to FIGS. 1A to 8 will be assigned with identical/similar reference numerals, and repetitive descriptions will be omitted.

According to one or more embodiments of the present disclosure, the display panel manufacturing method may include an operation of forming the barrier wall PW (refer to FIG. 11E), and an operation of inspecting the tip portion TP (refer to FIG. 11E) of the formed barrier wall PW (refer to FIG. 11E). Referring to FIG. 10, the display panel manufacturing method according to one or more embodiments of the present disclosure may include operation S100 of forming a preliminary barrier wall, operation S200 of forming a photoresist layer, operation S300 of firstly etching the preliminary barrier wall, operation S400 of secondly etching the preliminary barrier wall to form the barrier wall, and operation S500 of inspecting the tip portion of the barrier wall.

As illustrated in FIGS. 10 and 11A, the display panel manufacturing method may include operation S100 of forming the preliminary barrier wall PW-I.

The preliminary barrier wall PW-I may be formed on a preliminary display panel DP-I. The preliminary display panel DP-I may include a base layer BL, a circuit element layer DP-CL, an anode AE, a preliminary sacrificial pattern SP-I, and a preliminary pixel-defining layer PDL-I.

The circuit element layer DP-CL may be formed through a conventional circuit element manufacturing process of forming an insulating layer, a semiconductor layer, and a conductive layer by coating, deposition, or the like, and forming a semiconductor pattern, a conductive pattern, and a signal line by selectively making the insulating layer, the semiconductor layer, and the conductive layer subject to patterning by photolithography and etching processes.

The anode AE and the preliminary sacrificial pattern SP-I may be formed by the same patterning process. The preliminary pixel-defining layer PDL-I may cover both the anode AE and the preliminary sacrificial pattern SP-I. The preliminary pixel-defining layer PDL-I may correspond to a state before the above-described pixel opening OP-E (refer to FIG. 5) is defined. The preliminary sacrificial pattern SP-I may correspond to a state before the above-described sacrificial opening OP-S (refer to FIG. 5) is defined. The anode AE illustrated in FIG. 11A may correspond to one of the first, second, or third anodes AE1, AE2, or AE3 described above with reference to FIG. 6. The preliminary sacrificial pattern SP-I illustrated in FIG. 11A may correspond to a state before the sacrificial openings OP1-S, OP2-S, and OP3-S respectively corresponding to the first to third sacrificial patterns SP1, SP2, and SP3 (described above with reference to FIG. 6) are defined.

The operation of forming the preliminary barrier wall PW-I may include an operation of forming a first preliminary barrier wall layer L1-I and an operation of forming a second preliminary barrier wall layer L2-I.

The first preliminary barrier wall layer L1-I may be formed on the preliminary pixel-defining layer PDL-I. The operation of forming the first preliminary barrier wall layer L1-I may be performed by a process of depositing a conductive material. For example, the conductive material that forms the first preliminary barrier wall layer L1-I may include metal, metal nitride, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The metal nitride may include titanium nitride (TiN). The transparent conductive oxide may include indium tin oxide (ITO), indium zinc oxide (IZO), zinc oxide, indium oxide, indium gallium oxide, indium gallium zinc oxide (IGZO), or aluminum zinc oxide.

The second preliminary barrier wall layer L2-I may be formed on the first preliminary barrier wall layer L1-I. In one or more embodiments, the operation of forming the second preliminary barrier wall layer L2-I may be performed by a process of depositing a conductive material. For example, the conductive material that forms the second preliminary barrier wall layer L2-I may include metal, metal nitride, transparent conductive oxide (TCO), or a combination thereof. The metal may include gold (Au), silver (Ag), aluminum (Al), magnesium (Mg), lithium (Li), molybdenum (Mo), titanium (Ti), copper (Cu), or an alloy. The metal nitride may include titanium nitride (TIN). The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Alternatively, in one or more embodiments of the present disclosure, the second preliminary barrier wall layer L2-I may not include a metallic material. The second preliminary barrier wall layer L2-I may include an inorganic insulating material. In this case, the operation of forming the second preliminary barrier wall layer L2-I may be performed by a process of depositing an inorganic insulating material. For example, the second preliminary barrier wall layer L2-I may be formed of a silicon-based compound. For example, the second preliminary barrier wall layer L2-I may include at least one of silicon oxide SiOₓ, silicon nitride SiNₓ, or silicon oxy nitride SiOₓN_{y}.

For example, the conductive material that forms the first preliminary barrier wall layer L1-I may be aluminum (Al), and the conductive material that forms the second preliminary barrier wall layer L2-I may be titanium (Ti).

The formed preliminary barrier wall PW-I may include the first preliminary barrier wall layer L1-I and the second preliminary barrier wall layer L2-I.

Referring to FIGS. 10 and 11B, the display panel manufacturing method may include operation S200 of forming the photoresist layer PRL.

The photoresist layer PRL may be formed on the preliminary barrier wall PW-I. The photoresist layer PRL may be formed by forming a preliminary photoresist layer on the preliminary barrier wall PW-I, and thereafter making the preliminary photoresist layer subject to patterning by using a photo mask. Through the patterning process, the photoresist layer PRL including a first photo pattern PR1 and second photo patterns PR2 may be formed. A first photo opening OP1-PR and a second photo opening OP2-PR may be defined in the first photo pattern PR1. The first photo opening OP1-PR may overlap the anode AE. The second photo opening OP2-PR may not overlap the anode AE.

In FIG. 11B, only one first photo opening OP1-PR overlapping one anode AE is illustrated as an example. However, in one or more embodiments, a plurality of first photo openings OP1-PR may be provided. The first photo openings OP1-PR may be located to overlap the first anodes AE1 (refer to FIG. 6), the second anodes AE2 (refer to FIG. 6), or the third anodes AE3 (refer to FIG. 6). Alternatively, in one or more embodiments of the present disclosure, the first photo openings OP1-PR may be located to overlap the first anodes AE1 (refer to FIG. 6), the second anodes AE2 (refer to FIG. 6), and the third anodes AE3 (refer to FIG. 6).

The second photo patterns PR2 may be located in the second photo opening OP2-PR. The second photo patterns PR2 may include a 2-1 photo pattern PR2a and a 2-2 photo pattern PR2b. That is, the second photo patterns PR2 may include two patterns in one second photo opening OP2-PR.

On the section, the width of the 2-1 photo pattern PR2a in one direction (e.g., the first direction DR1) may be different from the width of the 2-2 photo pattern PR2b in the one direction (e.g., the first direction DR1). For example, on the section, the width of the 2-2 photo pattern PR2b in the first direction DR1 may be greater than the width of the 2-1 photo pattern PR2a in the first direction DR1.

Referring to FIGS. 10 and 11C to 11E, the display panel manufacturing method may include the operation of etching the preliminary barrier wall PW-I to form the barrier wall PW from the preliminary barrier wall PW-I. The operation of etching the preliminary barrier wall PW-I may be performed twice. The operation of etching the preliminary barrier wall PW-I may include operation S300 of firstly etching the preliminary barrier wall PW-I and operation S400 of secondly etching the preliminary barrier wall PW-I.

First, referring to FIGS. 10 and 11C, operation S300 of firstly etching the preliminary barrier wall PW-I may include an operation of dry etching the first preliminary barrier wall layer L1-I and the second preliminary barrier wall layer L2-I with the photoresist layer PRL as a mask. Through operation S300 of firstly etching the preliminary barrier wall PW-I, a preliminary barrier wall opening OP-PI and a preliminary inspection opening OP-INI may be formed in the preliminary barrier wall PW-I. The preliminary barrier wall opening OP-PI may be formed through the first photo opening OP1-PR, and the preliminary inspection opening OP-INI may be formed through the second photo opening OP2-PR. The preliminary barrier wall opening OP-PI may be defined by a first inner surface S1-PI of the first preliminary barrier wall layer L1-I and a second inner surface S2-PI of the second preliminary barrier wall layer L2-I. The preliminary inspection opening OP-INI may be defined by a third inner surface S3-PI of the first preliminary barrier wall layer L1-I, and a fourth inner surface S4-PI of the second preliminary barrier wall layer L2-I.

The dry etching process may be performed in an etching environment in which the etch selectivity between the first preliminary barrier wall layer L1-I and the second preliminary barrier wall layer L2-I is substantially the same. Accordingly, the first inner surface S1-PI of the first preliminary barrier wall layer L1-I, and the second inner surface S2-PI of the second preliminary barrier wall layer L2-I, may be substantially aligned with each other. The second inner surface S2-PI of the second preliminary barrier wall layer L2-I may not protrude when compared to the first inner surface S1-PI of the first preliminary barrier wall layer L1-I. In addition, the third inner surface S3-PI of the first preliminary barrier wall layer L1-I, and the fourth inner surface S4-PI of the second preliminary barrier wall layer L2-I, may be substantially aligned with each other. The fourth inner surface S4-PI of the second preliminary barrier wall layer L2-I may not protrude when compared to the third inner surface S3-PI of the first preliminary barrier wall layer L1-I.

In operation S300 of firstly etching the preliminary barrier wall PW-I, the initial inspection patterns INP-P may be formed together. The initial inspection patterns INP-P may be formed by making a portion of the preliminary barrier wall PW-I subject to patterning. The initial inspection patterns INP-P may be formed in the preliminary inspection opening OP-INI.

The initial inspection patterns INP-P may include a first initial inspection pattern INP1-P and a second initial inspection pattern INP2-P. The first initial inspection pattern INP1-P may be formed through the 2-1 photo pattern PR2a, and the second initial inspection pattern INP2-P may be formed through the 2-2 photo pattern PR2b.

The first initial inspection pattern INP1-P may include a first initial inspection pattern layer L1p1 and a second initial inspection pattern layer L2p1, and the second initial inspection pattern INP2-P may include a first initial inspection pattern layer L1p2 and a second initial inspection pattern layer L2p2. The first initial inspection pattern layers L1p1 and L1p2 of the first and second initial inspection patterns INP1-P and INP2-P may be formed by making a portion of the first preliminary barrier wall layer L1-I subject to patterning. That is, the first initial inspection pattern layers L1p1 and L1p2 may include the same material as the first preliminary barrier wall layer L1-I. The second initial inspection pattern layers L2p1 and L2p2 of the first and second initial inspection patterns INP1-P and INP2-P may be formed from the second preliminary barrier wall layer L2-I. That is, the second initial inspection pattern layers L2p1 and L2p2 may include the same material as the second preliminary barrier wall layer L2-I.

On the section, the first initial inspection pattern INP1-P may have a first initial width w1-P in one direction (e.g., the first direction DR1), and the second initial inspection pattern INP2-P may have a second initial width w2-P in the one direction (e.g., the first direction DR1). The first initial width w1-P may be different from the second initial width w2-P. For example, the second initial width w2-P may be greater than the first initial width w1-P. The first and second initial widths w1-P and w2-P may be defined based on the lower surfaces of the first initial inspection pattern layers L1p1 and L1p2.

Next, referring to FIGS. 10, 11D, and 11E, operation S400 of secondly etching the preliminary barrier wall PW-I may include an operation of wet etching the first preliminary barrier wall layer L1-I with the photoresist layer PRL as a mask. Through operation S400 of secondly etching the preliminary barrier wall PW-I, the barrier wall PW may be formed from the preliminary barrier wall PW-I. Meanwhile, in this specification, operation S400 of secondly etching the preliminary barrier wall PW-I may be referred to as the “undercut etching process”.

In one or more embodiments, operation S400 of secondly etching the preliminary barrier wall PW-I may include an operation of etching the first preliminary barrier wall layer L1-I by providing the chemical EC to the preliminary barrier wall PW-I having the preliminary barrier wall opening OP-PI and the preliminary inspection opening OP-INI defined therein. Meanwhile, in this specification, the chemical EC may refer to a processing liquid used for an etching process in the display panel manufacturing process.

The wet etching process may be performed in an environment in which the etch selectivity between the first preliminary barrier wall layer L1-I and the second preliminary barrier wall layer L2-I is large. In the undercut etching process, the etch rate of the first preliminary barrier wall layer L1-I may be higher than the etch rate of the second preliminary barrier wall layer L2-I. The degree to which the first preliminary barrier wall layer L1-I is etched may be higher than the degree to which the second preliminary barrier wall layer L2-I is etched. Accordingly, in the operation of secondly etching the preliminary barrier wall PW-I, only the first preliminary barrier wall layer L1-I may be etched, and the second preliminary barrier wall layer L2-I may not be etched or may not be substantially etched.

In operation S400 of secondly etching the preliminary barrier wall PW-I, the barrier wall PW including the first barrier wall layer L1 and the second barrier wall layer L2 may be formed. The barrier wall opening OP-P and the inspection opening OP-IN may be formed in the barrier wall PW. The barrier wall opening OP-P may be formed from the preliminary barrier wall opening OP-PI of the preliminary barrier wall PW-I, and the inspection opening OP-IN may be formed from the preliminary inspection opening OP-INI of the preliminary barrier wall PW-I.

The inner surface of the barrier wall PW that defines the barrier wall opening OP-P may have an undercut shape on the section. The first inner surface S1-P of the first barrier wall layer L1 may be recessed inward when compared to the second inner surface S2-P of the second barrier wall layer L2. The tip portion TP may be formed in the barrier wall PW by the portion of the second barrier wall layer L2 that protrudes toward the center of the anode AE when compared to the first barrier wall layer L1.

The barrier wall opening OP-P may include the first region A1 and the second region A2 sequentially located in the thickness direction (that is, the third direction DR3). The first region A1 of the barrier wall opening OP-P may be defined by the first inner surface S1-P of the first barrier wall layer L1, and the second region A2 of the barrier wall opening OP-P may be defined by the second inner surface S2-P of the second barrier wall layer L2. On the section, the width w-A2 of the second region A2 in one direction may be less than the width w-A1 of the first region A1 in the one direction. The inner surface of the barrier wall PW that defines the inspection opening OP-IN may have an undercut shape on the section. The third inner surface S3-P of the first barrier wall layer L1 may be recessed inward when compared to the fourth inner surface S4-P of the second barrier wall layer L2. The additional tip portion TP-A may be formed in the barrier wall PW by the portion of the second barrier wall layer L2 that protrudes toward the inspection pattern INP when compared to the first barrier wall layer L1.

The inspection opening OP-IN may include the third region A3 and the fourth region A4 sequentially located in the thickness direction (that is, the third direction DR3). The third region A3 of the inspection opening OP-IN may be defined by the third inner surface S3-P of the first barrier wall layer L1, and the fourth region A4 of the inspection opening OP-IN may be defined by the fourth inner surface S4-P of the second barrier wall layer L2. On the section, the fourth region A4 may have a narrower width than the third region A3.

In operation S400 of secondly etching the preliminary barrier wall PW-I, the inspection pattern INP may be formed from the initial inspection patterns INP-P. The wet etching process may be performed in an environment in which the etch selectivity between the first initial inspection pattern layers L1p1 and L1p2 and the second initial inspection pattern layers L2p1 and L2p2 is large. The etch rates of the first initial inspection pattern layers L1p1 and L1p2 may be higher than the etch rates of the second initial inspection pattern layers L2p1 and L2p2.

In operation S400 of secondly etching the preliminary barrier wall PW-I, the first initial inspection pattern INP1-P may be removed. The first initial inspection pattern layer L1p1 of the first initial inspection pattern INP1-P may be etched and removed. Accordingly, the second initial inspection pattern layer L2p1 of the first initial inspection pattern INP1-P and the 2-1 photo pattern PR2a may be separated and removed from the preliminary display panel DP-I (refer to FIG. 11A).

In operation S400 of secondly etching the preliminary barrier wall PW-I, the inspection pattern INP may be formed from the second initial inspection pattern INP2-P. In operation S400 of secondly etching the preliminary barrier wall PW-I, the inspection pattern INP may be formed by etching a portion of the first initial inspection pattern layer L1p2 of the second initial inspection pattern INP2-P, and by removing the second initial inspection pattern layer L2p2 of the second initial inspection pattern INP2-P from the first initial inspection pattern layer L1p2. The first initial inspection pattern layer L1p2 may be etched and may have a narrow width, and the second initial inspection pattern layer L2p2 may be removed away from the etched first initial inspection pattern layer L1p2 due to a decrease in adhesion with the etched first initial inspection pattern layer L1p2. The inspection pattern INP may be located in the third region A3 of the inspection opening OP-IN.

The display panel manufacturing method may include operation S500 of inspecting the tip portion TP of the barrier wall PW. The tip portion TP of the barrier wall PW may be inspected through the inspection pattern INP. For example, whether the tip portion TP is formed to have the length d-TP (refer to FIG. 5) within the suitable range may be determined by recognizing the degree to which the first initial inspection pattern layers L1p1 and L1p2 are etched.

A lower limit of the width of the first preliminary barrier wall layer L1-I etched in operation S400 of secondly etching the preliminary barrier wall PW-I may be predicted through the first initial inspection pattern INP1-P removed in operation S400 of secondly etching the preliminary barrier wall PW-I. In this specification, the width of the first preliminary barrier wall layer L1-I etched in operation S400 of secondly etching the preliminary barrier wall PW-I may correspond to the degree of depression from the first inner surface S1-PI of the first preliminary barrier wall layer L1-I before operation S400 of secondly etching the preliminary barrier wall PW-I to the first inner surface S1-P of the first barrier wall layer L1 after operation S400 of secondly etching the preliminary barrier wall PW-I.

The width of the first preliminary barrier wall layer L1-I etched in operation S400 of secondly etching the preliminary barrier wall PW-I may be greater than or equal to about half of the width w1-P of the first initial inspection pattern INP1-P. The length d-TP (refer to FIG. 5) of the tip portion TP formed in the barrier wall PW may be predicted through the width of the first preliminary barrier wall layer L1-I etched in operation S400 of secondly etching the preliminary barrier wall PW-I. Accordingly, a lower limit of the length d-TP (refer to FIG. 5) of the tip portion TP formed in the barrier wall PW may be predicted through the width w1-P of the first initial inspection pattern INP1-P. The length d-TP (refer to FIG. 5) of the tip portion TP may be predicted to be greater than or equal to about half of the width w1-P of the first initial inspection pattern INP1-P. Accordingly, when the tip portion TP suitably has a length above a level (e.g., predetermined level), whether the tip portion TP has a length above the level (e.g., predetermined level) may be suitably determined, based on whether the first initial inspection pattern INP1-P is removed.

An upper limit of the width of the first preliminary barrier wall layer L1-I etched in operation S400 of secondly etching the preliminary barrier wall PW-I may be predicted through the second initial inspection pattern INP2-P left in operation S400 of secondly etching the preliminary barrier wall PW-I.

The width of the first preliminary barrier wall layer L1-I etched in operation S400 of secondly etching the preliminary barrier wall PW-I may be less than about half of the width w2-P of the second initial inspection pattern INP2-P. Accordingly, an upper limit of the length d-TP (refer to FIG. 5) of the tip portion TP formed in the barrier wall PW may be predicted through the width w2-P of the second initial inspection pattern INP2-P. The length d-TP (refer to FIG. 5) of the tip portion TP may be predicted to be less than the width w2-P of the second initial inspection pattern INP2-P. Accordingly, when the tip portion TP suitably has a length below a level (e.g., predetermined level), whether the tip portion TP has a length below the level (e.g., predetermined level) may also be suitably determined, based on whether the second initial inspection pattern INP2-P remains.

Whether the tip portion TP is formed to have the length d-TP (refer to FIG. 5) within the suitable range may be determined by determining whether the initial inspection patterns INP-P are removed or whether the initial inspection patterns INP-P remain. Whether the initial inspection patterns INP-P are removed or remain may be determined through optical inspection, and thus the inspection may be suitably performed without destruction of the formed result.

According to one or more embodiments, the width of the first preliminary barrier wall layer L1-I etched in operation S400 of secondly etching the preliminary barrier wall PW-I may be identified through the second initial inspection pattern INP2-P and the inspection pattern INP. The width of the first preliminary barrier wall layer L1-I etched in operation S400 of secondly etching the preliminary barrier wall PW-I may be determined to be substantially the same as the second initial width w2-P of the second initial inspection pattern INP2-P minus the width w-INP of the inspection pattern INP. Accordingly, the length d-TP (refer to FIG. 5) of the tip portion TP formed in the barrier wall PW may be identified. The length d-TP (refer to FIG. 5) of the tip portion TP may be determined to be substantially the same as half of a value obtained by subtracting the width w-INP of the inspection pattern INP from the second initial width w2-P of the second initial inspection pattern INP2-P.

The inspection pattern INP may be provided as a single layer as only a portion of the first initial inspection pattern layer L1p2 remains, and may not include a tip portion as the second initial inspection pattern layer L2p2 is removed. Accordingly, the width of the etched first preliminary barrier wall L1-I may be suitably inspected through an optical inspection device, and thus the length d-TP (refer to FIG. 5) of the tip portion TP may be identified without destruction of the formed result. In one or more embodiments, the width of the etched first preliminary barrier wall L1-I may be measured using an optical measuring instrument, for example, a CD-METER.

Meanwhile, the second barrier wall layer L2 of the barrier wall PW may include a conductive material (e.g., metal), and light is not able to transmit the second barrier wall layer L2. Therefore, it may be difficult to directly measure the length d-TP (refer to FIG. 5) of the tip portion TP using an optical measuring instrument. Furthermore, because the barrier wall PW has an undercut shape, it may be difficult to directly measure the length d-TP (refer to FIG. 5) of the tip portion TP using an atomic force microscope (AFM). Therefore, when an inspection pattern is not formed as above, it may be difficult to measure the length d-TP (refer to FIG. 5) of the tip portion TP without cutting the barrier wall PW.

FIGS. 12A to 12C are sectional views illustrating some of the operations of the display panel manufacturing method according to one or more embodiments of the present disclosure. In describing FIGS. 12A to 12C, components identical or similar to the components described above with reference to FIGS. 1A to 9 will be assigned with identical/similar reference numerals, and repetitive descriptions will be omitted.

Referring to FIGS. 10 and 12A, the display panel manufacturing method may include operation S200 of forming a photoresist layer PRL′. The photoresist layer PRL′ may include a first photo pattern PR1′ and second photo patterns PR2′, and the second photo patterns PR2′ may include a 2-1 photo pattern PR2a′, a 2-2 photo pattern PR2b′, and a 2-3 photo pattern PR2c′. That is, the second photo patterns PR2′ may include three patterns in one second photo opening OP2-PR.

On the section, the width of the 2-1 photo pattern PR2a′ in one direction (e.g., the first direction DR1), the width of the 2-2 photo pattern PR2b′ in the one direction (e.g., the first direction DR1), and the width of the 2-3 photo pattern PR2c′ in the one direction (e.g., the first direction DR1) may be different from one another. For example, on the section, the width of the 2-2 photo pattern PR2b′ in the first direction DR1 may be greater than the width of the 2-1 photo pattern PR2a′ in the first direction DR1, and may be less than the width of the 2-3 photo pattern PR2c′ in the first direction DR1.

Referring to FIGS. 10 and 12B, the display panel manufacturing method may include operation S300 of firstly etching the preliminary barrier wall PW-I.

In operation S300 of firstly etching the preliminary barrier wall PW-I, the initial inspection patterns INP-P′ may be formed together. The initial inspection patterns INP-P′ may include a first initial inspection pattern INP1-P′, a second initial inspection pattern INP2-P′, and a third initial inspection pattern INP3-P′. That is, three initial inspection patterns may be formed. The first to third initial inspection patterns INP1-P′, INP2-P′, and INP3-P′ may be formed through the 2-1, 2-2, and 2-3 photo patterns PR2a′, PR2b′, and PR2c′, respectively.

The first to third initial inspection patterns INP1-P′, INP2-P′, and INP3-P′ may include first initial inspection pattern layers L1p1′, L1p2′, and L1p3′ and second initial inspection pattern layers L2p1′, L2p2′, and L2p3′, respectively. The first initial inspection pattern layers L1p1′, L1p2′, and L1p3′ may be formed by making a portion of the first preliminary barrier wall layer L1-I subject to patterning. The second initial inspection pattern layers L2p1′, L2p2′, and L2p3′ may be formed from the second preliminary barrier wall layer L2-I.

On the section, the first to third initial inspection patterns INP1-P′, INP2-P′, and INP3-P′ may have first to third initial widths w1-P′, w2-P′, and w3-P′, respectively, in one direction (e.g., the first direction DR1). The first to third initial widths w1-P′, w2-P′, and w3-P′ may be different from one another. For example, the second initial width w2-P′ may be greater than the first initial width w1-P′, and may be less than the third initial width w3-P′. The difference between the first and second initial widths w1-P′ and w2-P′ and the difference between the second and third initial widths w2-P′ and w3-P′ in FIG. 12B may be less than the difference between the first and second initial widths w1-P and w2-P in FIG. 11C.

Referring to FIGS. 10, 12B, and 12C, the display panel manufacturing method may include operation S400 of secondly etching the preliminary barrier wall PW-I and operation S500 of inspecting the tip portion TP of the barrier wall PW.

In operation S400 of secondly etching the preliminary barrier wall PW-I, the inspection pattern INP′ may be formed from the initial inspection patterns INP-P′. In one or more embodiments, the first initial inspection pattern INP1-P′ may be removed, and the second and third initial inspection patterns INP2-P′ and INP3-P′ may be left. Accordingly, in operation S500 of inspecting the tip portion TP of the barrier wall PW, the length d-TP (refer to FIG. 5) of the tip portion TP may be predicted to be greater than or equal to about half of the width w1-P′ of the first initial inspection pattern INP1-P′. Furthermore, in operation S500 of inspecting the tip portion TP of the barrier wall PW, the length d-TP (refer to FIG. 5) of the tip portion TP may be predicted to be less than about half of the width w2-P′ of the second initial inspection pattern INP2-P′.

In addition, the length d-TP (refer to FIG. 5) of the tip portion TP may be predicted, based on the difference between the width w2-P′ of the second initial inspection pattern INP2-P′ and the width w-INP1′ of the first inspection pattern INP1′, and based on the difference between the width w3-P′ of the third initial inspection pattern INP3-P′ and the width w-INP2′ of the second inspection pattern INP2′.

The three or more initial inspection patterns INP-P′ may be provided, and thus the length d-TP (refer to FIG. 5) of the tip portion TP may be more precisely predicted than when the two initial inspection patterns INP-P (refer to FIG. 11C) are provided.

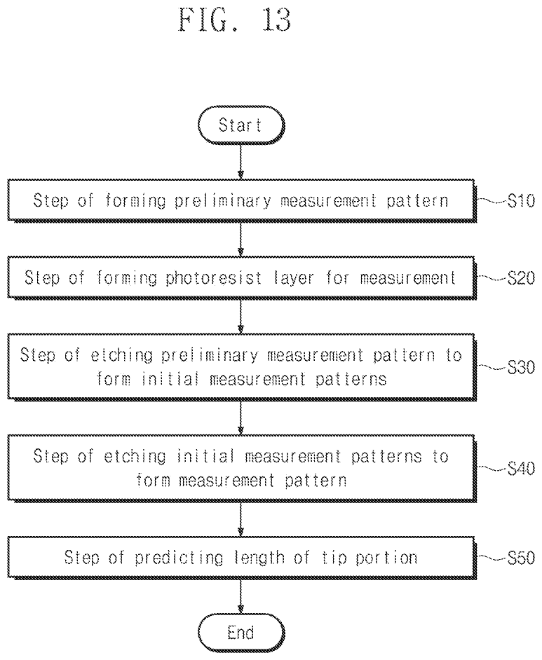

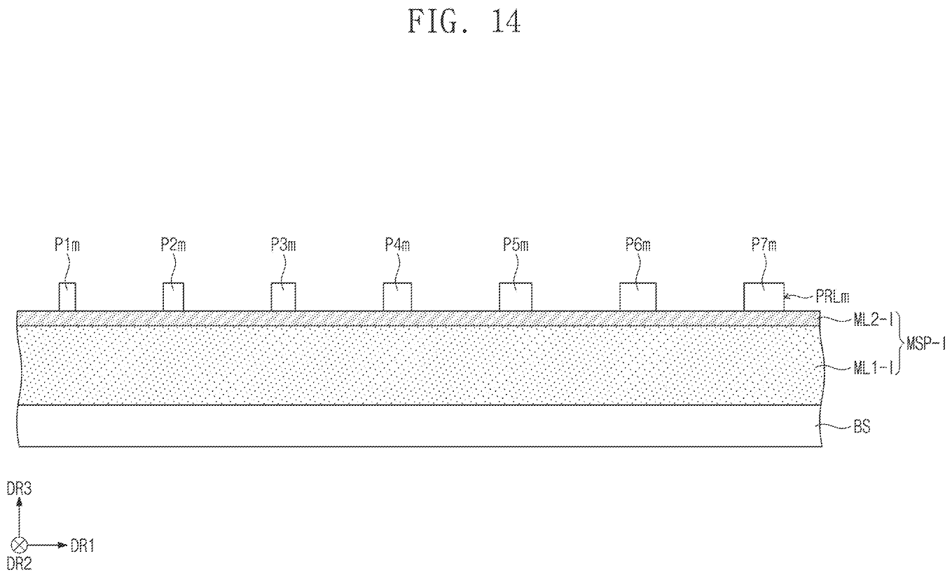

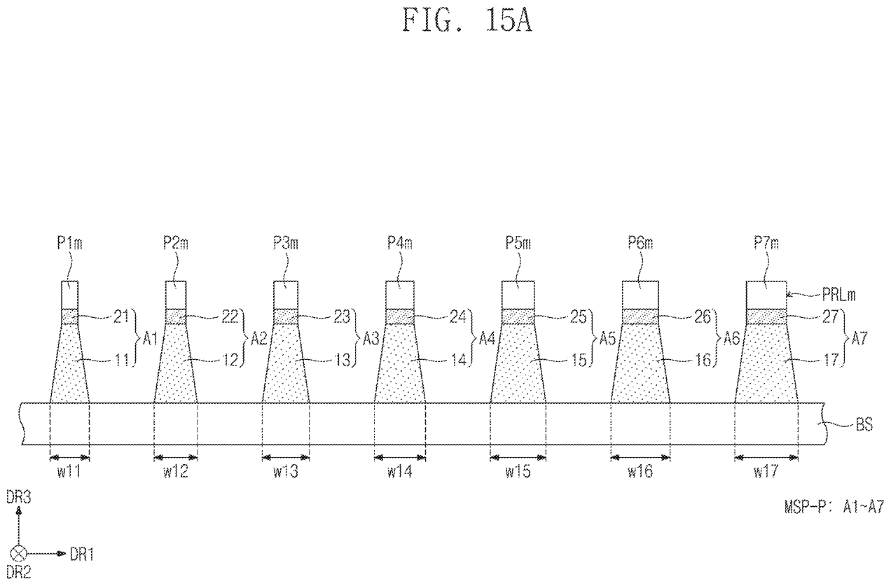

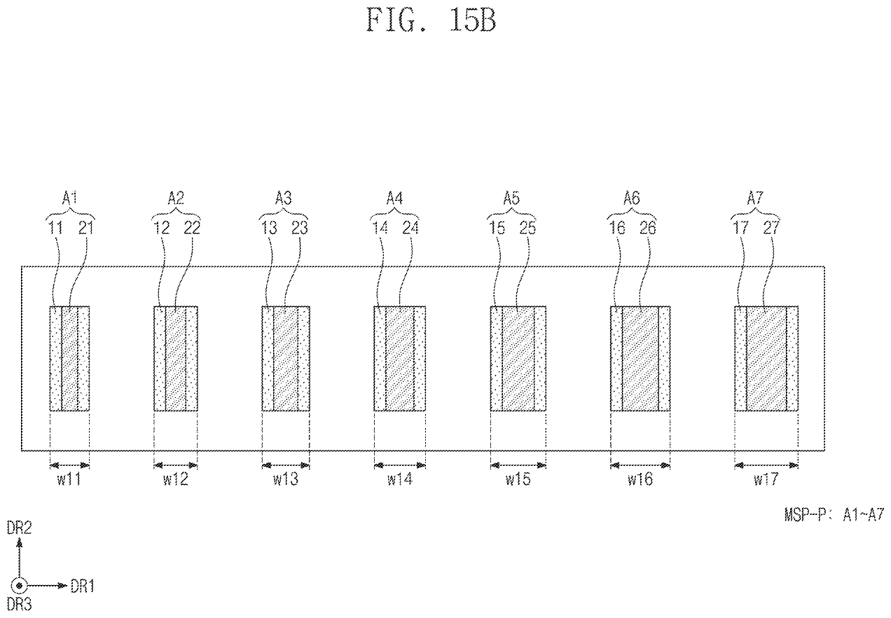

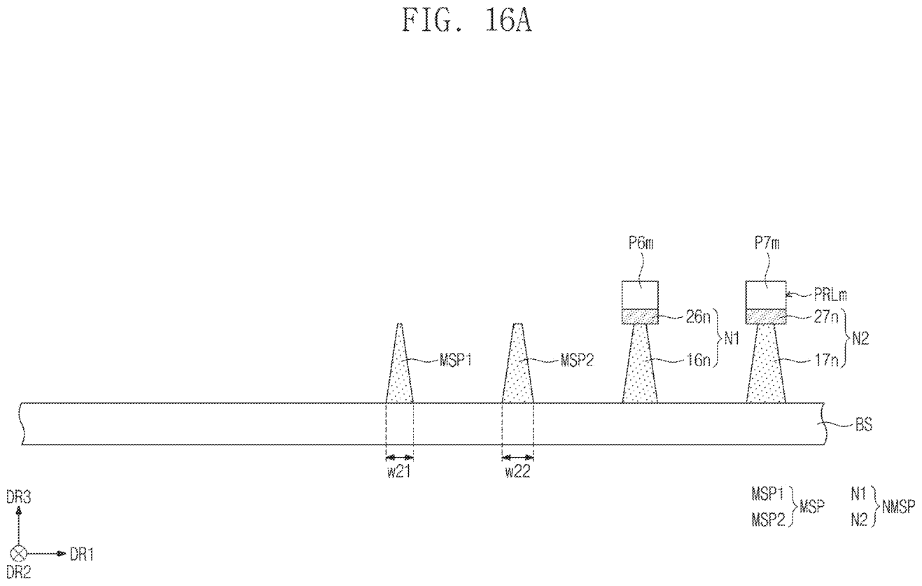

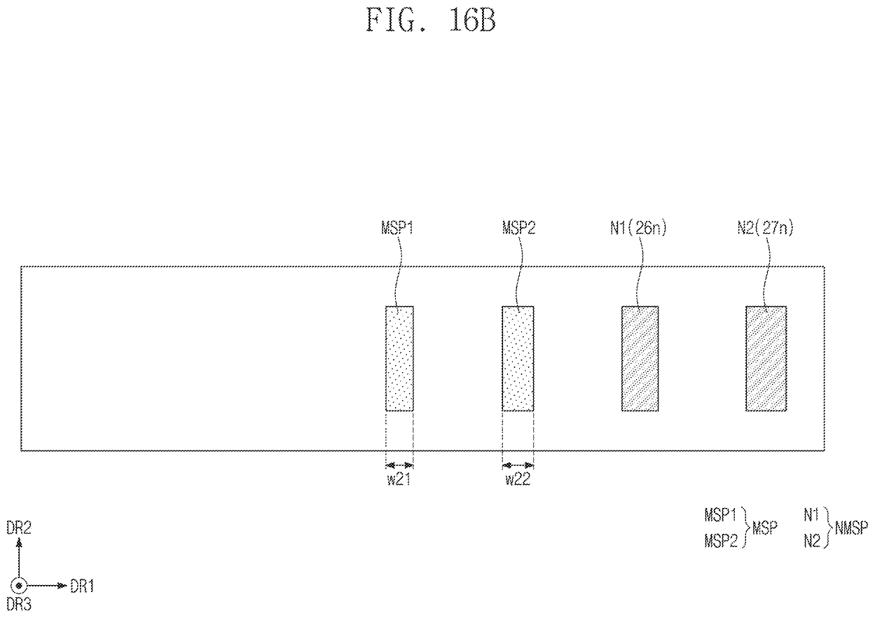

FIG. 13 is a flowchart illustrating a display panel manufacturing method according to one or more embodiments of the present disclosure. FIG. 14 is a sectional view illustrating a part of operations of the display panel manufacturing method according to one or more embodiments of the present disclosure. FIG. 15A is a sectional view illustrating a part of the operations of the display panel manufacturing method according to one or more embodiments of the present disclosure. FIG. 15B is a plan view illustrating a part of the operations of the display panel manufacturing method according to one or more embodiments of the present disclosure. FIG. 16A is a sectional view illustrating a part of the operations of the display panel manufacturing method according to one or more embodiments of the present disclosure. FIG. 16B is a plan view illustrating a part of the operations of the display panel manufacturing method according to one or more embodiments of the present disclosure. In describing FIGS. 13 to 16B, components identical or similar to the components described above with reference to FIGS. 1A to 12C will be assigned with identical/similar reference numerals, and repetitive descriptions will be omitted.

According to one or more embodiments of the present disclosure, the display panel manufacturing method may include an operation of predicting the length of the tip portion TP (refer to FIG. 11E) to be formed in the barrier wall PW (refer to FIG. 11E) before the formation of the barrier wall PW (refer to FIG. 11E). Referring to FIG. 13, the display panel manufacturing method according to one or more embodiments of the present disclosure may include operation S10 of forming a preliminary measurement pattern, operation S20 of forming a photoresist layer for measurement, operation S30 of etching the preliminary measurement pattern to form initial measurement patterns, operation S40 of etching the initial measurement patterns to form a measurement pattern, and operation S50 of predicting the length of the tip portion.

Referring to FIG. 14, the display panel manufacturing method may include operation S10 of forming the preliminary measurement pattern MSP-I. The preliminary measurement pattern MSP-I may be formed on a substrate BS for measurement.

The operation of forming the preliminary measurement pattern MSP-I may include an operation of forming a first preliminary measurement layer ML1-I on the substrate BS for measurement, and an operation of forming a second preliminary measurement layer ML2-I on the first preliminary measurement layer ML1-I. The preliminary measurement pattern MSP-I may include the first preliminary measurement layer ML1-I and the second preliminary measurement layer ML2-I.

The first preliminary measurement layer ML1-I may include the same material as the first barrier wall layer L1 (refer to FIG. 11E) of the barrier wall PW (refer to FIG. 11E) to be manufactured. In consideration of the material of the first barrier wall layer L1 (refer to FIG. 11E) to be manufactured, the operation of forming the first preliminary measurement layer ML1-I may be performed through a deposition process of the same type as the deposition process in the operation of forming the first preliminary barrier wall layer L1-I (refer to FIG. 11B). In addition, the first preliminary measurement layer ML1-I may be formed to have substantially the same thickness as the first barrier wall layer L1 (refer to FIG. 11E) to be manufactured.

The second preliminary measurement layer ML2-I may include the same material as the second barrier wall layer L2 (refer to FIG. 11E) of the barrier wall PW (refer to FIG. 11E) to be manufactured. In consideration of the material of the second barrier wall layer L2 (refer to FIG. 11E) to be manufactured, the operation of forming the second preliminary measurement layer ML2-I may be performed through a deposition process of the same type as the deposition process in the operation of forming the second preliminary barrier wall layer L2-I (refer to FIG. 11B). In addition, the second preliminary measurement layer ML2-I may be formed to have substantially the same thickness as the second barrier wall layer L2 (refer to FIG. 11E) to be manufactured.

The display panel manufacturing method may include operation S20 of forming the photoresist layer PRLm for measurement.

The photoresist layer PRLm for measurement may be formed on the preliminary measurement pattern MSP-I. The photoresist layer PRLm for measurement may be formed by forming a preliminary photoresist layer on the preliminary measurement pattern MSP-I, and thereafter making the preliminary photoresist layer subject to patterning by using a photo mask. The photoresist layer PRLm for measurement that includes a plurality of photo patterns for measurement may be formed through the patterning process.

FIG. 14 illustrates an example that the photo patterns for measurement include seven photo patterns (hereinafter, referred to as the first, second, third, fourth, fifth, sixth, and seventh measurement photo patterns P1m, P2m, P3m, P4m, P5m, P6m, and P7m). On the section, the widths of the first to seventh measurement photo patterns P1m, P2m, P3m, P4m, P5m, P6m, and P7m in the first direction DR1 may be different from one another. For example, the widths of the first to seventh measurement photo patterns P1m, P2m, P3m, P4m, P5m, P6m, and P7m in the first direction DR1 on the section may consecutively increase from the first measurement photo pattern P1m toward the seventh measurement photo pattern P7m.

Referring to FIGS. 14 to 15B, the display panel manufacturing method may include operation S30 of etching the preliminary measurement pattern MSP-I to form the initial measurement patterns MSP-P from the preliminary measurement pattern MSP-I. FIG. 15B illustrates a plan view of the initial measurement patterns MSP-P.

Operation S30 of etching the preliminary measurement pattern MSP-I may include an operation of dry etching the first preliminary measurement layer ML1-I and the second preliminary measurement layer ML2-I with the photoresist layer PRLm for measurement as a mask. Operation S30 of etching the preliminary measurement pattern MSP-I may be performed similarly to operation S300 (refer to FIG. 10) of firstly etching the preliminary barrier wall PW-I (refer to FIG. 11C), which is to be performed when the barrier wall PW (refer to FIG. 11E) is manufactured. For example, etching conditions identical to the etching conditions (e.g., a gas to be injected, the time during which the gas is injected, and the like) to be provided in operation S300 (refer to FIG. 10) of firstly etching the preliminary barrier wall PW-I (refer to FIG. 11C) may be provided in operation S30 of etching the preliminary measurement pattern MSP-I.

The plurality of initial measurement patterns MSP-P may be formed through operation S30 of etching the preliminary measurement pattern MSP-I. The plurality of initial measurement patterns MSP-P may include first, second, third, fourth, fifth, sixth, and seventh initial measurement patterns A1, A2, A3, A4, A5, A6, and A7. The first to seventh initial measurement patterns A1, A2, A3, A4, A5, A6, and A7 may be formed from the first to seventh measurement photo patterns P1m, P2m, P3m, P4m, P5m, P6m, and P7m, respectively.

The first to seventh initial measurement patterns A1, A2, A3, A4, A5, A6, and A7 may respectively include first initial measurement layers 11, 12, 13, 14, 15, 16, and 17 and second initial measurement layers 21, 22, 23, 24, 25, 26, and 27. The first initial measurement layers 11, 12, 13, 14, 15, 16, and 17 may be formed by making the first preliminary measurement layer ML1-I subject to patterning, and the second initial measurement layers 21, 22, 23, 24, 25, 26, and 27 may be formed by making the second preliminary measurement layer ML2-I subject to patterning.

Operation S30 of etching the preliminary measurement pattern MSP-I may be performed in an etching environment in which the etch selectivity between the first preliminary measurement layer ML1-I and the second preliminary measurement layer ML2-I is substantially the same. Accordingly, in the first to seventh initial measurement patterns A1, A2, A3, A4, A5, A6, and A7, the outer surfaces of the first initial measurement layers 11, 12, 13, 14, 15, 16, and 17 may be substantially aligned with the outer surfaces of the second initial measurement layers 21, 22, 23, 24, 25, 26, and 27. The outer surfaces of the second initial measurement layers 21, 22, 23, 24, 25, 26, and 27 may not protrude when compared to the outer surfaces of the first initial measurement layers 11, 12, 13, 14, 15, 16, and 17.

The first, second, third, fourth, fifth, sixth, and seventh initial measurement patterns A1, A2, A3, A4, A5, A6, and A7 may have first, second, third, fourth, fifth, sixth, and seventh initial widths w11, w12, w13, w14, w15, w16, and w17, respectively, in one direction. The first to seventh initial widths w11, w12, w13, w14, w15, w16, and w17 may be defined as the widths of lower surfaces of the first initial measurement layers 11, 12, 13, 14, 15, 16, and 17, respectively. The first to seventh initial widths w11, w12, w13, w14, w15, w16, and w17 may be gradually increased from the first initial width w11 toward the seventh initial width w17. That is, the first to seventh initial measurement patterns A1, A2, A3, A4, A5, A6, and A7 may be formed such that the widths are increased from the first initial measurement pattern A1 toward the seventh initial measurement pattern A7.

In FIGS. 15A and 15B, the first initial measurement layers 11, 12, 13, 14, 15, 16, and 17 are illustrated as having a tapered shape. However, without being limited thereto, the first initial measurement layers 11, 12, 13, 14, 15, 16, and 17 may be formed to have surfaces perpendicular to the substrate BS for measurement.

Referring to FIGS. 14 and 15A to 16B, the display panel manufacturing method may include operation S40 of etching the initial measurement patterns MSP-P to form at least one measurement pattern MSP from the initial measurement patterns MSP-P. FIG. 16B illustrates a plan view of patterns remaining after operation S40 of etching the initial measurement patterns MSP-P.

Operation S40 of etching the initial measurement patterns MSP-P may include an operation of wet etching the first initial measurement layers 11, 12, 13, 14, 15, 16, and 17 with the photoresist layer PRLm for measurement as a mask. Operation S40 of etching the initial measurement patterns MSP-P may be performed similarly to operation S400 (refer to FIG. 10) of secondly etching the preliminary barrier wall PW-I (refer to FIG. 11D), which is to be performed when the barrier wall PW (refer to FIG. 11E) is manufactured. For example, etching conditions identical to the etching conditions (e.g., a chemical to be injected, the time during which the chemical is injected, and the like) to be provided in operation S400 (refer to FIG. 10) of secondly etching the preliminary barrier wall PW-I (refer to FIG. 11D) may be provided in operation S40 of etching the initial measurement patterns MSP-P.

Through the operation of etching the initial measurement patterns MSP-P, the measurement patterns MSP may be formed from the initial measurement patterns MSP-P. The operation of etching the initial measurement patterns MSP-P may be performed in an environment in which the etch selectivity between the first initial measurement layers 11, 12, 13, 14, 15, 16, and 17 and the second initial measurement layers 21, 22, 23, 24, 25, 26, and 27 is large. The etch rates of the first initial measurement layers 11, 12, 13, 14, 15, 16, and 17 may be higher than the etch rates of the second initial measurement layers 21, 22, 23, 24, 25, 26, and 27.

In one or more embodiments, the first to third initial measurement patterns A1, A2, and A3 (or, referred to as the first type patterns) may be removed. In the operation of etching the initial measurement patterns MSP-P, the first initial measurement layers 11, 12, and 13 of the first to third initial measurement patterns A1, A2, and A3 may be etched and removed. Accordingly, the second initial measurement layers 21, 22, and 23 of the first to third initial measurement patterns A1, A2, and A3 may be separated and removed from the substrate BS for measurement. The first to third measurement photo patterns P1m, P2m, and P3m may also be removed together.

In one or more embodiments, the measurement patterns MSP may include first and second measurement patterns MSP1 and MSP2. The first and second measurement patterns MSP1 and MSP2 may be formed from the fourth and fifth initial measurement patterns A4 and A5 (or, referred to as the second type patterns), respectively.

The first measurement pattern MSP1 may be formed by etching a portion of the first initial measurement layer 14 of the fourth initial measurement pattern A4, and by removing the second initial measurement layer 24 of the fourth initial measurement pattern A4 from the first initial measurement layer 14. The first initial measurement layer 14 may be etched, and may have a relatively narrow width, and the second initial measurement layer 24 may be removed away from the first initial measurement layer 14 due to a decrease in adhesion with the partially etched first initial measurement layer 14. The fourth measurement photo pattern P4m may also be removed together.

The second measurement pattern MSP2 may be formed by etching a portion of the first initial measurement layer 15 of the fifth initial measurement pattern A5, and by removing the second initial measurement layer 25 of the fifth initial measurement pattern A5 from the first initial measurement layer 15. The first initial measurement layer 15 may be etched, and may have a narrow width, and the second initial measurement layer 25 may be removed away from the first initial measurement layer 15 due to a decrease in adhesion with the partially etched first initial measurement layer 15. The fifth measurement photo pattern P5m may also be removed together.

In one or more embodiments, through the operation of etching the initial measurement patterns MSP-P, non-measurement patterns NMSP may be formed from some of the initial measurement patterns MSP-P. The non-measurement patterns NMSP may include a first non-measurement pattern N1 and a second non-measurement pattern N2. The first and second non-measurement patterns N1 and N2 may be formed from the sixth and seventh initial measurement patterns A6 and A7 (or, referred to as the third type patterns), respectively.

The first and second non-measurement patterns N1 and N2 may include first non-measurement pattern layers 16n and 17n and second non-measurement pattern layers 26n and 27n, respectively.

The first non-measurement pattern layer 16n of the first non-measurement pattern N1 may be a portion remaining after a portion of the first initial measurement layer 16 of the sixth initial measurement pattern A6 is etched, and the second initial measurement layer 26 of the sixth initial measurement pattern A6 may remain to form the second non-measurement pattern layer 26n of the first non-measurement pattern N1. The second initial measurement layer 26 of the sixth initial measurement pattern A6 may not be etched, or may not be substantially etched. The sixth measurement photo pattern P6m may also remain together.

The first non-measurement pattern layer 17n of the second non-measurement pattern N2 may be a portion remaining after a portion of the first initial measurement layer 17 of the seventh initial measurement pattern A7 is etched, and the second initial measurement layer 27 of the seventh initial measurement pattern A7 may remain to form the second non-measurement pattern layer 27n of the second non-measurement pattern N2. The second initial measurement layer 27 of the seventh initial measurement pattern A7 may not be etched, or may not be substantially etched. The seventh measurement photo pattern P7m may also remain together.

When the first initial measurement layers 16 and 17 remain with a width above a corresponding level (e.g., predetermined level), the second initial measurement layers 26 and 27 may have a sufficient adhesive force with the remaining first initial measurement layers 16 and 17. Thus, the second initial measurement layers 26 and 27 may also remain.

The display panel manufacturing method may include operation S50 of predicting the length d-TP (refer to FIG. 5) of the tip portion TP (refer to FIG. 11E).

A lower limit of the length of the tip portion in the barrier wall to be manufactured may be predicted through the removed initial measurement patterns A1, A2, and A3 (or, the first type patterns). The lower limit of the length of the tip portion may be predicted through the initial measurement pattern having the greatest width among the removed initial measurement patterns A1, A2, and A3. For example, the lower limit of the length of the tip portion may be predicted to be about half of the width of the third initial measurement pattern A3.

The length of the tip portion in the barrier wall to be manufactured may be predicted through the measurement patterns MSP1 and MSP2 and the initial measurement patterns A4 and A5 (or, the second type patterns) that form the measurement patterns MSP1 and MSP2. For example, the length of the tip portion may be predicted to be a value obtained by subtracting the width w21 of the first measurement pattern MSP1 from the fourth initial width w14 of the fourth initial measurement pattern A4. Alternatively, the length of the tip portion may be predicted to be a value obtained by subtracting the width w22 of the second measurement pattern MSP2 from the fifth initial width w15 of the fifth initial measurement pattern A5. Meanwhile, in one or more embodiments, the length of the tip portion may be predicted to be the average of a value predicted through the first measurement pattern MSP1 and a value predicted through the second measurement pattern MSP2.

Unlike the non-measurement patterns NMSP (or, the third type patterns), the measurement patterns MSP may not include tip portions because the second initial measurement layers 24 and 25 are removed. Accordingly, the widths of the etched first initial measurement layers 14 and 15 may be suitably inspected through an optical inspection device, and thus the length of the tip portion may be predicted without destruction of the formed result.

An effect of improving moisture permeability, whether contact resistance is secured, front efficiency, and the like may vary depending on the length of the tip portion in the barrier wall. For example, as the length of the tip portion is increased, the effect of improving moisture permeability may be obtained, and the contact resistance may be secured. In contrast, as the length of the tip portion is decreased, the area of an emissive region may be increased, and thus the front efficiency may be improved. Accordingly, the length of the tip portion in the barrier wall is suitably precisely controlled depending on characteristics suitable for the display panel to be manufactured. According to the present disclosure, the length of a formed barrier wall may be suitably inspected, or the length of a barrier wall to be formed may be suitably predicted.

According to the present disclosure, the display panel may include the inspection pattern for inspecting the tip portion of the barrier wall. Accordingly, the process reliability of the display panel may be improved.

According to the present disclosure, the length of the tip portion of the barrier wall may be previously predicted through the measurement pattern having the same configuration as the barrier wall.

While the present disclosure has been described with reference to embodiments thereof, it will be apparent to those of ordinary skill in the art that various changes and modifications may be made thereto without departing from the spirit and scope of the present disclosure as set forth in the following claims, with functional equivalents thereof to be included therein.

What is claimed is:

1. A display panel comprising:
a barrier wall defining a barrier wall opening and an inspection opening, and comprising a first barrier wall layer, and a second barrier wall layer above the first barrier wall layer; and
an inspection pattern in the inspection opening, and comprising a same material as the first barrier wall layer,
wherein the barrier wall opening comprises:
a first region defined by an inner surface of the first barrier wall layer; and
a second region defined by an inner surface of the second barrier wall layer, and having a smaller width than a width of the first region.

2. The display panel of claim 1, wherein the inspection opening comprises:
a third region defined by an inner surface of the first barrier wall layer; and
a fourth region defined by an inner surface of the second barrier wall layer, and
wherein the inspection pattern is in the third region, and is not in the fourth region.

3. The display panel of claim 1, wherein the inspection opening is provided in plural,
wherein the inspection pattern is provided in plural, the inspection patterns being respectively in the inspection openings.

4. The display panel of claim 1, wherein the inspection opening is provided in plural,
wherein the inspection pattern is provided in plural,
wherein the inspection patterns having different respective widths are in each of the inspection openings.

5. The display panel of claim 1, further comprising a light-emitting element in the barrier wall opening, and comprising an anode, an emission pattern, and a cathode contacting the barrier wall in the barrier wall opening.

6. The display panel of claim 5, further comprising a thin film encapsulation layer above the light-emitting element, and contacting the inspection pattern.

7. A method for manufacturing a display panel, the method comprising:
forming a preliminary barrier wall comprising a first preliminary barrier wall layer, and a second preliminary barrier wall layer above the first preliminary barrier wall layer;
firstly etching the preliminary barrier wall to form initial inspection patterns; and
secondly etching the preliminary barrier wall to form a barrier wall comprising a first barrier wall layer, and a second barrier wall layer above the first barrier wall layer, and to form an inspection pattern from the initial inspection patterns, the inspection pattern comprising a same material as the first barrier wall layer.

8. The method of claim 7, wherein the firstly etching comprises etching the first preliminary barrier wall layer and the second preliminary barrier wall layer, and
wherein the secondly etching comprises etching the first preliminary barrier wall layer.

9. The method of claim 8, wherein the initial inspection patterns comprise:
a first initial inspection pattern layer patterned from the first preliminary barrier wall layer; and
a second initial inspection pattern layer patterned from the second preliminary barrier wall layer.

10. The method of claim 9, wherein the initial inspection patterns comprise a first initial inspection pattern, and a second initial inspection pattern having a greater width than the first initial inspection pattern, and
wherein the secondly etching comprises removing the first initial inspection pattern, removing the second initial inspection pattern layer of the second initial inspection pattern, and allowing a portion of the first initial inspection pattern layer of the second initial inspection pattern to remain to form the inspection pattern.

11. The method of claim 8, wherein the secondly etching comprises forming a tip portion comprising a portion of the second barrier wall layer protruding further than the first barrier wall layer.

12. The method of claim 11, further comprising determining a length of the tip portion based on whether the initial inspection patterns are removed by the secondly etching.

13. The method of claim 11, wherein the method further comprises:
forming a preliminary measurement pattern comprising a first preliminary measurement layer comprising a same material as the first preliminary barrier wall layer, and a second preliminary measurement layer comprising a same material as the second preliminary barrier wall layer above the first preliminary measurement layer;
etching the preliminary measurement pattern to form initial measurement patterns;
etching the initial measurement patterns having different respective widths to form a measurement pattern; and
predicting a length of the tip portion.

14. The method of claim 13, wherein the etching of the preliminary measurement pattern is performed under substantially a same etching condition as the firstly etching of the preliminary barrier wall, and
wherein the etching of the initial measurement patterns is performed under substantially a same etching condition as the secondly etching of the preliminary barrier wall.

15. The method of claim 13, wherein the initial measurement patterns comprise:
a first initial measurement layer patterned from the first preliminary measurement layer; and
a second initial measurement layer patterned from the second preliminary measurement layer.

16. The method of claim 15, wherein the initial measurement patterns comprise a first type pattern and a second type pattern, and
wherein the etching of the initial measurement patterns comprises removing the first type pattern, removing the second initial measurement layer of the second type pattern, and allowing a portion of the first initial measurement layer of the second type pattern to remain to form the measurement pattern.

17. The method of claim 16, wherein the predicting the length of the tip portion comprises predicting a lower limit of the length to be substantially equal to a width of the removed first type pattern.

18. The method of claim 16, wherein the predicting the length of the tip portion comprises predicting the length to be a difference between a width of the second type pattern and a width of the measurement pattern.

19. A method for manufacturing a display panel, the method comprising:
forming initial measurement patterns comprising a first initial measurement layer, and a second initial measurement layer above the first initial measurement layer;
forming a measurement pattern from the initial measurement patterns by allowing the first initial measurement layer of one initial measurement pattern among the initial measurement patterns to remain, and by removing the second initial measurement layer of the one initial measurement pattern;
predicting a length of a tip portion through the measurement pattern; and
forming a barrier wall having the tip portion defined therein, and comprising a first barrier wall layer comprising a same material as the first initial measurement layer, and a second barrier wall layer above the first barrier wall layer and comprising a same material as the second initial measurement layer.

20. The method of claim 19, wherein the forming of the barrier wall comprises:
forming a preliminary barrier wall comprising a first preliminary barrier wall layer, and a second preliminary barrier wall layer above the first preliminary barrier wall layer;
firstly etching the preliminary barrier wall such that the first preliminary barrier wall layer and the second preliminary barrier wall layer are etched; and
secondly etching the preliminary barrier wall such that the first preliminary barrier wall layer is etched,
wherein the forming of the initial measurement patterns is performed under substantially a same etching condition as the firstly etching, and
wherein the forming of the measurement pattern is performed under substantially a same etching condition as the secondly etching.
